(19) United States
(12) Patent Application Publication
(10) Pub. No.: US 2026/0136632 A1
(43) Pub. Date: May 14, 2026

(54) INTEGRATED CIRCUIT DEVICE

(71) Applicant: Samsung Electronics Co., Ltd., Suwon-si (KR)

(72) Inventors: Kyul Ko, Suwon-si (KR); Junsoo Kim, Suwon-si (KR); Daehyun Moon, Suwon-si (KR); Jeonghoon Oh, Suwon-si (KR); Sungho Jang, Suwon-si (KR)

(21) Appl. No.: 19/244,899

(22) Filed: Jun. 20, 2025

(30) Foreign Application Priority Data
Nov. 13, 2024 (KR) 10-2024-0161330

(51) Int. Cl. H10D 64/27; H10D 64/68

(52) U.S. Cl. CPC H10D 64/518; H10D 64/685

(57) ABSTRACT

An integrated circuit device includes an active region, a silicon oxide dielectric film covering the active region, a metal oxide dielectric film apart from the active region with the silicon oxide dielectric film therebetween and including a first local region and a second local region that has a dopant content ratio greater than that of the first local region, a metal-containing word line apart from the silicon oxide dielectric film with each of the first local region and the second local region of the metal oxide dielectric film therebetween, and a doped silicon layer including a portion contacting the metal-containing word line and facing the second local region of the metal oxide dielectric film.

### CROSS-REFERENCE TO RELATED APPLICATION(S)

This application is based on and claims priority under 35 U.S.C. § 119 to Korean Patent Application No. 10-2024-0161330, filed on Nov. 13, 2024, in the Korean Intellectual Property Office, the disclosure of which is incorporated by reference herein in its entirety.

### BACKGROUND

An increasing degree of integration of integrated circuit devices may lead to a decrease in pitches of a plurality of word lines and an increase in gate induced drain leakage (GIDL) current, which may adversely affect refresh characteristics of integrated circuit devices. Therefore, to suppress GIDL current and precisely control threshold voltages of gate electrodes, techniques using metal-oxide-semiconductor field-effect transistors (MOSFETs) having multi-threshold voltages (multi-Vt) have been developed.

### SUMMARY

The present disclosure provides an integrated circuit device that has a structure capable of reducing resistance in a word line, suppressing leakage current, and improving electrical characteristics such as refresh characteristics while providing a transistor having multi-threshold voltages.

According to an aspect of the present disclosure, an integrated circuit device includes an active region, a silicon oxide dielectric film covering the active region, a metal oxide dielectric film, which is apart from the active region with the silicon oxide dielectric film therebetween and includes a first local region and a second local region, the second local region having a dopant content ratio greater than that of the first local region, a metal-containing word line, which is apart from the silicon oxide dielectric film with each of the first local region and the second local region of the metal oxide dielectric film therebetween, and a doped silicon layer including a portion that is in contact with the metal-containing word line and faces the second local region of the metal oxide dielectric film.

According to another aspect of the present disclosure, an integrated circuit device includes a substrate in which a word line trench is arranged to extend lengthwise in a first horizontal direction, a silicon oxide dielectric film covering an inner surface of the word line trench, a metal oxide dielectric film, which is in contact with the silicon oxide dielectric film in the word line trench and apart from the substrate with the silicon oxide dielectric film therebetween and comprises a first local region and a second local region, the first local region being located in a lower portion of the word line trench, and the second local region being closer to an entrance of the word line trench than the first local region and having a dopant content ratio greater than that of the first local region, a metal-containing word line arranged on the metal oxide dielectric film in the word line trench, the metal-containing word line being apart from the silicon oxide dielectric film with each of the first local region and the second local region of the metal oxide dielectric film therebetween, and a doped silicon layer, which is at least partially buried in the metal-containing word line in the word line trench and includes a portion facing the second local region of the metal oxide dielectric film.

According to another aspect of the present disclosure, an integrated circuit device includes a conductive line extending lengthwise in a first horizontal direction, a plurality of active regions arranged over the conductive line to be apart from each other in the first horizontal direction, each of the plurality of active regions being configured to be connected to the conductive line, a metal-containing word line between a pair of active regions that are selected from the plurality of active regions and adjacent to each other, the metal-containing word line extending in a second horizontal direction that is perpendicular to the first horizontal direction, a silicon oxide dielectric film arranged between a first active region selected from the pair of active regions and the metal-containing word line to cover a sidewall of the first active region, a metal oxide dielectric film arranged between the silicon oxide dielectric film and the metal-containing word line and including a first local region and a second local region, the first local region being in contact with a first portion of the silicon oxide dielectric film, and the second local region being in contact with a second portion, which is adjacent to the first portion, of the silicon oxide dielectric film and having a dopant content ratio greater than that of the first local region, and a doped silicon layer including a portion that faces the second local region of the metal oxide dielectric film with the metal-containing word line therebetween.

### BRIEF DESCRIPTION OF THE DRAWINGS

Implementations will be more clearly understood from the following detailed description taken in conjunction with the accompanying drawings in which:

FIG. 1 is a schematic planar layout illustrating main components of a cell array area of an integrated circuit device according to implementations;

FIG. 2 is a cross-sectional view of some components of the integrated circuit device of FIG. 1, taken along a line X1-X1′ of FIG. 1;

FIG. 3 is a cross-sectional view of some components of the integrated circuit device of FIG. 1, taken along a line X2-X2′ of FIG. 1;

FIG. 4 is a cross-sectional view of some components of the integrated circuit device of FIG. 1, taken along a line Y1-Y1′ of FIG. 1;

FIG. 5 is an enlarged cross-sectional view of a region EX1 of FIG. 4;

FIG. 6 is a cross-sectional view illustrating an integrated circuit device according to some implementations;

FIG. 7 is an enlarged cross-sectional view of a region EX2 of FIG. 6;

FIG. 8 is a planar layout diagram illustrating some components of an integrated circuit device according to some implementations;

FIG. 9 is a cross-sectional view of the integrated circuit device of FIG. 8, taken along a line X1-X1′ of FIG. 8;

FIG. 10 is a cross-sectional view illustrating an integrated circuit device according to some implementations;

FIGS. 11A to 11I are cross-sectional views respectively illustrating a sequence of processes of a method of fabricating an integrated circuit device, according to implementations;

FIGS. 12A to 12I are cross-sectional views respectively illustrating a sequence of processes of a method of fabricating an integrated circuit device, according to some implementations;

FIGS. 13A to 13P are cross-sectional views respectively illustrating a sequence of processes of a method of fabricating an integrated circuit device, according to some implementations;

FIGS. 14A to 14C are cross-sectional views respectively illustrating a sequence of more detailed processes of the process described with reference to FIG. 13H; and

FIGS. 15A to 15C are cross-sectional views respectively illustrating a sequence of processes of a method of fabricating an integrated circuit device, according to some implementations.

### DETAILED DESCRIPTION

Hereinafter, implementations of the present disclosure will be described in detail with reference to the accompanying drawings. Like components are denoted by like reference numerals throughout the specification, and repeated descriptions thereof are omitted.

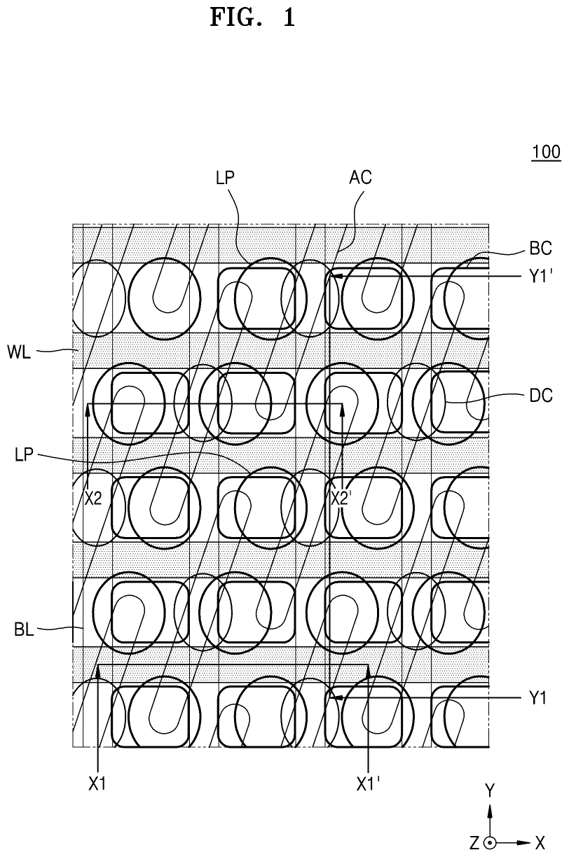

FIG. 1 is a schematic planar layout illustrating main components of a cell array area of an integrated circuit device 100 according to implementations.

Referring to FIG. 1, the integrated circuit device 100 may include a plurality of active regions AC arranged to extend lengthwise in an oblique direction with respect to a first horizontal direction (an X direction) and a second horizontal direction (a Y direction) in an X-Y plane. A plurality of word lines WL may extend lengthwise in the first horizontal direction (the X direction) across the plurality of active regions AC. Each of the plurality of word lines WL may have a substantially constant width in the first horizontal direction (the X direction) that is a length direction thereof.

A plurality of bit lines BL may be arranged over the plurality of word lines WL to extend parallel to each other and in the second horizontal direction (the Y direction). Each of the plurality of bit lines BL may be connected to each of the plurality of active regions AC via a direct contact DC.

A plurality of buried contacts BC may be arranged between two adjacent bit lines BL from among the plurality of bit lines BL. A plurality of conductive landing pads LP may be respectively arranged on the plurality of buried contacts BC. Each of the plurality of buried contacts BC and each of the plurality of conductive landing pads LP may connect a lower electrode of a capacitor, which is formed over the plurality of bit lines BL, to an active region AC. Each of the plurality of conductive landing pads LP may be arranged to at least partially overlap a buried contact BC.

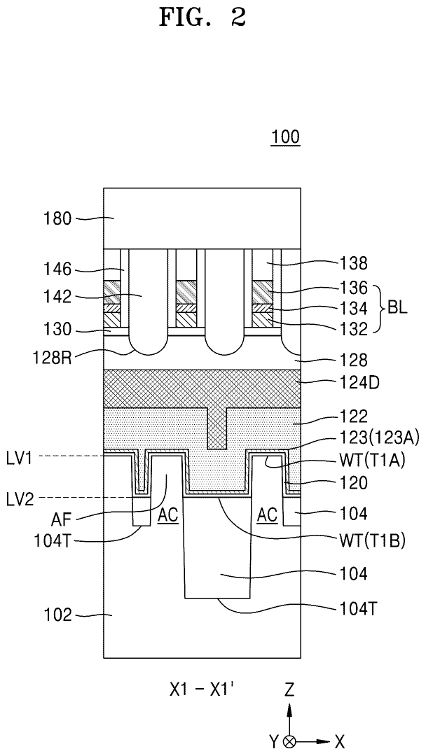

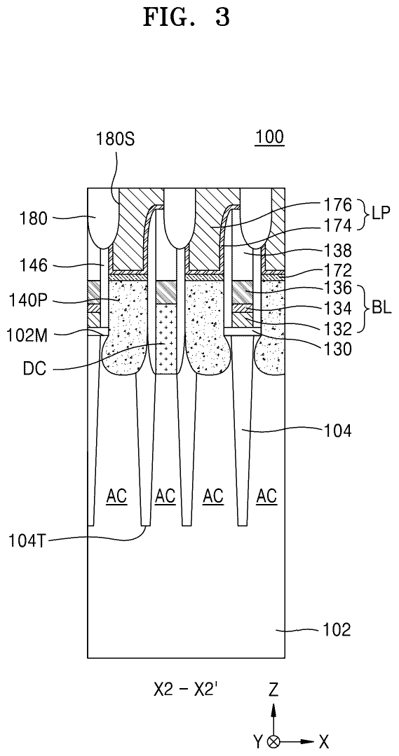

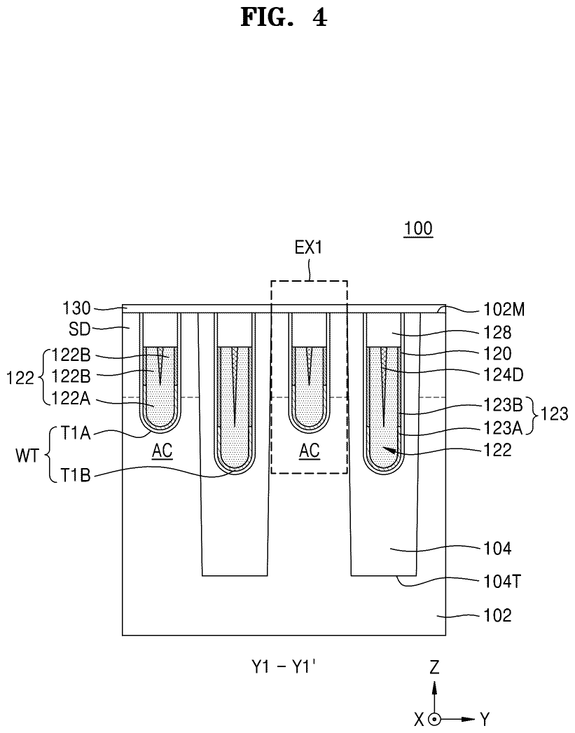

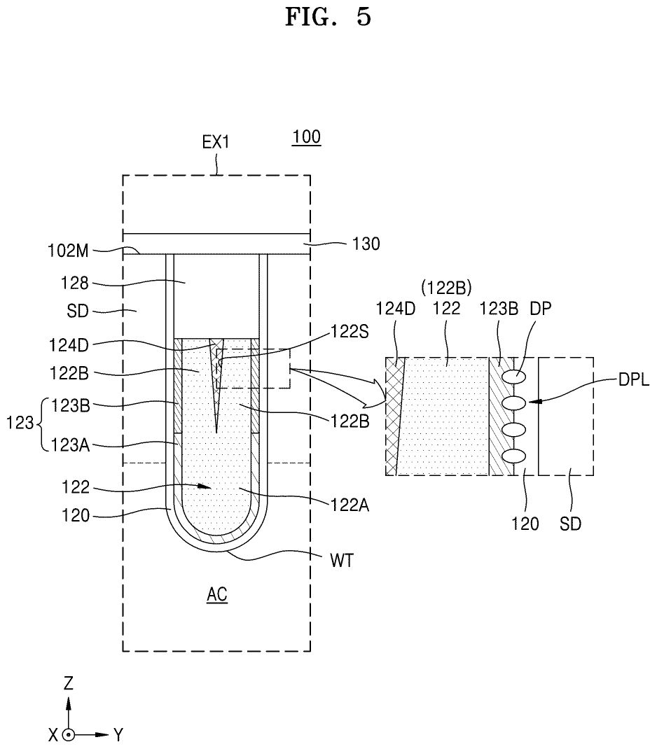

FIGS. 2 to 5 are cross-sectional views illustrating the integrated circuit device 100 according to implementations, and in particular, FIG. 2 is a cross-sectional view of some components of the integrated circuit device 100, taken along a line X1-X1′ of FIG. 1, FIG. 3 is a cross-sectional view of some components of the integrated circuit device 100, taken along a line X2-X2′ of FIG. 1, FIG. 4 is a cross-sectional view of some components of the integrated circuit device 100, taken along a line Y1-Y1′ of FIG. 1, and FIG. 5 is an enlarged cross-sectional view of a region EX1 of FIG. 4.

Referring to FIGS. 2 to 5, the integrated circuit device 100 includes a substrate 102 in which a device isolation trench 104T is formed. The device isolation trench 104T may be filled with a device isolation film 104. The plurality of active regions AC may be defined in the substrate 102 by the device isolation trench 104T and the device isolation film 104.

The device isolation film 104 may be arranged on the substrate 102 to surround the plurality of active regions AC. The device isolation film 104 may include a silicon oxide film, a silicon nitride film, or a combination thereof. A vertical level of the lower surface of the device isolation trench 104T may vary depending on positions thereof. As used herein, the term “vertical level” refers to a height in a vertical direction (a Z direction or a-Z direction) from a main surface 102M of the substrate 102.

In some implementations, the substrate 102 may include silicon, for example, monocrystalline silicon, polycrystalline silicon, or amorphous silicon. In some implementations, the substrate 102 may include at least one selected from Ge, SiGe, SiC, GaAs, InAs, and InP. In some implementations, the substrate 102 may include a conductive region, for example, a dopant-doped well or a dopant-doped structure.

A plurality of word line trenches WT may be formed in the substrate 102 and may extend in the first horizontal direction (the X direction) to be parallel to each other. Each of the plurality of word line trenches WT may have a line shape extending lengthwise in the first horizontal direction (the X direction) across the plurality of active regions AC and the device isolation film 104. In each of the plurality of word line trenches WT, the width of an entrance portion, which is closest to the main surface 102M of the substrate 102, in the second horizontal direction (the Y direction) may be greater than the width of a bottom portion, which is farthest from the main surface 102M of the substrate 102, in the second horizontal direction (the Y direction).

The inside of each of the plurality of word line trenches WT may be filled with a silicon oxide dielectric film 120, a metal-containing word line 122, a metal oxide dielectric film 123, a doped silicon layer 124D, and an insulating capping pattern 128. The metal-containing word line 122 may correspond to the word line WL of FIG. 1.

As shown in FIG. 2, in each of the plurality of word line trenches WT, vertical levels of the respective lower surfaces of portions on the plurality of active regions AC may be higher than vertical levels of the respective lower surfaces of portions on the device isolation film 104. Therefore, a lower surface profile of each of the plurality of word line trenches WT may have an uneven shape, and the lower surface of the metal-containing word line 122 may have an uneven shape in correspondence with the lower surface profile of the word line trench WT. In the plurality of active regions AC, a plurality of fin areas AF may be formed to protrude upwards in the vertical direction (the Z direction) from under the metal-containing word line 122 toward the metal-containing word line 122 in correspondence with the lower surface profile of the word line trench WT. As shown in FIGS. 2 and 4, each of the plurality of word line trenches WT may include a first trench portion T1A, which is located in the substrate 102 and has the lowermost surface at a first vertical level LV1, and a second trench portion T1B, which is located in the device isolation film 104 and has the lowermost surface at a second vertical level LV2 that is lower than the first vertical level LV1.

The silicon oxide dielectric film 120 may cover the plurality of active regions AC and the device isolation film 104 and may conformally cover an inner surface of the word line trench WT to contact the plurality of active regions AC and the device isolation film 104. The silicon oxide dielectric film 120 may include a silicon oxide film, for example, a SiO₂ film. The silicon oxide dielectric film 120 may have, but is not limited to, a thickness of about 10 nm to about 30 nm.

The metal oxide dielectric film 123 is apart from an active region AC and the device isolation film 104 with the silicon oxide dielectric film 120 therebetween. The metal oxide dielectric film 123 may include a high-k film having a dielectric constant higher than that of a silicon oxide film. The high-k film may include a metal oxide. In some implementations, the metal oxide dielectric film 123 may include a titanium oxide film.

The metal oxide dielectric film 123 may include a first local region 123A and a second local region 123B, which respectively have different dopant contents. In the metal oxide dielectric film 123, the first local region 123A is farther from the main surface 102M of the substrate 102 than the second local region 123B, and the second local region 123B is closer to the main surface 102M of the substrate 102 than the first local region 123A. That is, the second local region 123B is closer to the entrance of the word line trench WT than the first local region 123A. The second local region 123B extends in the vertical direction (the Z direction) from the upper surface, which is closest to the entrance of the word line trench WT, of the metal oxide dielectric film 123 by as much as a length that is less than the length of the word line trench WT in the vertical direction (the Z direction). In the metal oxide dielectric film 123, a dopant content ratio in the second local region 123B may be greater than a dopant content ratio in the first local region 123A. The second local region 123B of the metal oxide dielectric film 123 may include a dopant selected from phosphorus (P), boron (B), arsenic (As), germanium (Ge), and a combination thereof.

In some implementations, the dopant content ratio in the second local region 123B of the metal oxide dielectric film 123 may be constant. In some implementations, the dopant content ratio in the second local region 123B of the metal oxide dielectric film 123 may gradually decrease toward the first local region 123A in the vertical direction (the Z direction) from the upper surface of the metal oxide dielectric film 123. The first local region 123A of the metal oxide dielectric film 123 may include no dopant or may include a dopant in an amount equal to or less than a detection limit even though including the dopant.

The metal-containing word line 122 may include a metal-containing film. The metal-containing film may include a conductive metal nitride film. In addition, the metal-containing word line 122 may include one or more non-metallic elements. For example, the metal-containing film may include, but is not limited to, a TiN film. The metal-containing word line 122 may be arranged on the metal oxide dielectric film 123 to fill a lower space of the word line trench WT, which is a portion of the word line trench WT, and may extend lengthwise in the first horizontal direction (the X direction). The metal-containing word line 122 is apart from the silicon oxide dielectric film 120 with each of the first local region 123A and the second local region 123B of the metal oxide dielectric film 123 therebetween.

As shown in detail in FIGS. 4 and 5, the metal-containing word line 122 may include a lower electrode portion 122A and two upper branch electrode portions 122B integrally connected to the lower electrode portion 122A and branched from the lower electrode portion 122A toward the main surface 102M of the substrate 102. The lower electrode portion 122A may be in contact with the first local region 123A of the metal oxide dielectric film 123, and each of the two upper branch electrode portions 122B may be in contact with the second local region 123B of the metal oxide dielectric film 123.

In each of a plurality of metal-containing word lines 122, the lower electrode portion 122A may have a plug shape having no space therein. Two upper branch electrode portions 122B constituting one metal-containing word line 122 may be arranged in the word line trench WT and may extend upwards in the vertical direction (the Z direction) from the lower electrode portion 122A to define, together with the lower electrode portion 122A, an upper internal space 122S.

The doped silicon layer 124D may be arranged in the word line trench WT and may fill the upper internal space 122S defined by the lower electrode portion 122A and the two upper branch electrode portions 122B of the metal-containing word line 122. At least a portion of the doped silicon layer 124D may be buried in the upper internal space 122S, which is an inner space of the metal-containing word line 122. In the upper internal space 122S, the doped silicon layer 124D may be in contact with the metal-containing word line 122. The doped silicon layer 124D may be located apart from the second local region 123B of the metal oxide dielectric film 123 with an upper branch electrode portion 122B of the metal-containing word line 122 therebetween to contact the upper branch electrode portion 122B.

In the upper internal space 122S, the doped silicon layer 124D may have a shape having a gradually increasing width in the second horizontal direction (the Y direction) away from the lower electrode portion 122A in the vertical direction (the Z direction). The doped silicon layer 124D may include a portion facing the second local region 123B of the metal oxide dielectric film 123 in the second horizontal direction (the Y direction).

The doped silicon layer 124D may include doped amorphous silicon. The doped silicon layer 124D may include a dopant including the same element as a dopant element in the second local region 123B of the metal oxide dielectric film 123. In some implementations, the doped silicon layer 124D may include a dopant selected from phosphorus (P), boron (B), arsenic (As), germanium (Ge), and a combination thereof.

As shown in FIG. 5, an interface dipole layer DPL may be arranged between the second local region 123B of the metal oxide dielectric film 123 and the silicon oxide dielectric film 120. The interface dipole layer DPL may include a plurality of dipoles DP arranged along an interface between the second local region 123B of the metal oxide dielectric film 123 and the silicon oxide dielectric film 120.

The interface dipole layer DPL may be present between the second local region 123B of the metal oxide dielectric film 123 and the silicon oxide dielectric film 120 but may not be present between the first local region 123A of the metal oxide dielectric film 123 and the silicon oxide dielectric film 120. The second local region 123B of the metal oxide dielectric film 123 and the interface dipole layer DPL may each face the doped silicon layer 124D in the second horizontal direction (the Y direction), and the length of each of the second local region 123B of the metal oxide dielectric film 123 and the interface dipole layer DPL in the vertical direction (the Z direction) may be equal or similar to the length of the doped silicon layer 124D in the vertical direction (the Z direction). In the vertical direction (the Z direction), the length of each of the doped silicon layer 124D and the interface dipole layer DPL may be less than the length of the metal-containing word line 122.

The interface dipole layer DPL may include a plurality of dipoles, which are formed by interactions between dopant atoms derived from the second local region 123B of the metal oxide dielectric film 123 and oxygen atoms derived from the silicon oxide dielectric film 120. For example, when the second local region 123B of the metal oxide dielectric film 123 includes a titanium oxide film doped with phosphorus (P) atoms and the silicon oxide dielectric film 120 includes a silicon oxide film, the interface dipole layer DPL may include a plurality of dipoles, which are formed by dipole bonding between phosphorus (P) atoms derived from the second local region 123B of the metal oxide dielectric film 123 and oxygen atoms derived from the silicon oxide dielectric film 120. In some implementations, the density of dipoles in the interface dipole layer DPL may increase toward the upper surface of each of second local region 123B of the metal oxide dielectric film 123 and the silicon oxide dielectric film 120 and may decrease toward the first local region 123A of the metal oxide dielectric film 123.

Because the interface dipole layer DPL is arranged between the second local region 123B of the metal oxide dielectric film 123 and the silicon oxide dielectric film 120, a work function may be locally modulated by the interface dipole layer DPL in a buried channel array transistor (BCAT) structure that includes the metal-containing word line 122 including a single metal-containing film, and thus, a dual-gate transistor structure may be obtained.

In a transistor, a threshold voltage depends on a flat-band voltage, and the flat-band voltage depends on a work function. The work function may be engineered by various methods. For example, the work function may be adjusted by a constituent material of a gate electrode of the transistor, a material between the gate electrode and a channel, or the like. The flat-band voltage may be shifted by increasing or decreasing the work function. When the work function is high, the flat-band voltage may be shifted in a positive direction, and when the work function is low, the flat-band voltage may be shifted in a negative direction. As such, the threshold voltage may be adjusted by a shift of the flat-band voltage.

The integrated circuit device 100 according to the present disclosure includes the interface dipole layer DPL arranged along the interface between the second local region 123B of the metal oxide dielectric film 123 and the silicon oxide dielectric film 120. The interface dipole layer DPL may locally modulate the work function such that an effective work function value of the metal-containing word line 122 including a single metal-containing film decreases. Therefore, the flat-band voltage may be reduced by the interface dipole layer DPL, an increase in gate-induced drain leakage (GIDL) current may be suppressed, and the threshold voltage of the transistor including the metal-containing word line 122 may be precisely controlled, thereby preventing the deterioration of data retention time and improving refresh characteristics.

The insulating capping pattern 128 may fill an upper space of the word line trench WT. The insulating capping pattern 128 may be arranged in the word line trench WT to cover the upper surface of each of the metal-containing word line 122, the second local region 123B of the metal oxide dielectric film 123, and the doped silicon layer 124D. The insulating capping pattern 128 may have a flat lower surface contacting the upper surface of each of the metal-containing word line 122, the second local region 123B of the metal oxide dielectric film 123, and the doped silicon layer 124D, in the word line trench WT. The insulating capping pattern 128 may have a sidewall contacting the silicon oxide dielectric film 120. The upper surface of the insulating capping pattern 128 may be coplanar with the upper surface of the silicon oxide dielectric film 120. In some implementations, the insulating capping pattern 128 may include a silicon nitride film, a silicon oxynitride film, a silicon oxide film, or a combination thereof. In an example, the insulating capping pattern 128 may include a silicon nitride film. In another example, the insulating capping pattern 128 may include a silicon oxide film, which is in contact with the upper surface of each of the metal-containing word line 122, the second local region 123B of the metal oxide dielectric film 123, and the doped silicon layer 124D, and a silicon nitride film, which is arranged on the silicon oxide film to fill the upper space of the word line trench WT.

A plurality of source/drain regions SD may be respectively arranged in the plurality of active regions AC on both sides of the plurality of metal-containing word lines 122. Each of the plurality of source/drain regions SD may include an impurity region including impurity ions implanted into the substrate 102. The interface dipole layer DPL, which is arranged along the interface between the second local region 123B of the metal oxide dielectric film 123 and the silicon oxide dielectric film 120, may face a pair of source/drain regions SD respectively located on both sides of the silicon oxide dielectric film 120 based on the second horizontal direction (the Y direction). A work function in the upper branch electrode portion 122B, which is an upper portion of the metal-containing word line 122, may be modulated by the interface dipole layer DPL, and thus, may be less than a work function in the lower electrode portion 122A. Therefore, the metal-containing word line 122 may have a dual-work function structure. Herein, a work function refers to an effective work function. The dual-work function structure is a result obtained because, in a structure in which each of the first local region 123A and the second local region 123B of the metal oxide dielectric film 123 surrounding the metal-containing word line 122 is in contact with the silicon oxide dielectric film 120, there is no dipole at the interface between the first local region 123A and the silicon oxide dielectric film 120 or there are dipoles in an ignorable amount not substantially affecting the work function of the metal-containing word line 122 even though there are dipoles at the interface, and there is the interface dipole layer DPL, which includes a plurality of dipoles in a sufficient amount to modulate the work function of the metal-containing word line 122, at the interface between the second local region 123B and the silicon oxide dielectric film 120.

In each of the plurality of metal-containing word lines 122, the upper branch electrode portion 122B having a relatively low work function due to the interface dipole layer DPL may be arranged on the lower electrode portion 122A having a relatively high work function in the metal-containing word line 122, and thus, the upper branch electrode portion 122B having a relatively low work function may be arranged closer to a source/drain region SD. Therefore, the upper branch electrode portion 122B of the metal-containing word line 122 may have a structure in which the area overlapping the source/drain region SD including an impurity region in the second horizontal direction (the Y direction) is larger than that in the lower electrode portion 122A. Therefore, in the integrated circuit device 100, an increase in GIDL current may be suppressed, and the deterioration of data retention time may be prevented, thereby improving refresh characteristics. In addition, because the lower electrode portion 122A in each of the plurality of metal-containing word lines 122 of the integrated circuit device 100 has a relatively high work function, the resistance in the metal-containing word line 122 may be reduced, and a threshold voltage targeted by a transistor may be precisely controlled. Therefore, the integrated circuit device 100 may secure stable electrical characteristics.

In addition, each of the plurality of metal-containing word lines 122, which each function as a BCAT-structure word line in the integrated circuit device 100, may include only a metal-containing structure and may not include a material having relatively large resistance, such as polysilicon. Therefore, the volume occupied by a metal in each of the plurality of metal-containing word lines 122 may be increased, thereby reducing the resistance in each of the plurality of metal-containing word lines 122.

As shown in FIGS. 2 to 4, the main surface 102M of the substrate 102, the device isolation film 104, and the insulating capping pattern 128 may be covered by a buffer insulating film 130. The buffer insulating film 130 may include an oxide film, a nitride film, or a combination thereof. As shown in FIG. 3, a plurality of direct contacts DC may be respectively arranged on portions of the plurality of active regions AC. As shown in FIGS. 2 and 3, the plurality of bit lines BL may extend lengthwise in the second horizontal direction (the Y direction) on the buffer insulating film 130 and the plurality of direct contacts DC. The plurality of bit lines BL may be respectively covered by a plurality of insulating capping patterns 138.

A plurality of conductive plugs 140P and a plurality of insulating fences 142 may be alternately arranged one-by-one in a line in the second horizontal direction (the Y direction) between a pair of bit lines BL adjacent to each other from among the plurality of bit lines BL. The plurality of insulating fences 142 may respectively fill a plurality of recesses 128R, which are formed in the upper surface of the insulating capping pattern 128, and may be arranged one-by-one between each of the plurality of conductive plugs 140P. Both sidewalls of each of the plurality of conductive plugs 140P in the second horizontal direction (the Y direction) may be respectively covered by the plurality of insulating fences 142. The plurality of conductive plugs 140P arranged in a line in the second horizontal direction (the Y direction) may be insulated from each other by the plurality of insulating fences 142. The plurality of conductive plugs 140P may respectively constitute the plurality of buried contacts BC shown in FIG. 1.

Each of the plurality of bit lines BL may be connected to the active region AC via the direct contact DC. One direct contact DC and a pair of conductive plugs 140P facing each other with the one direct contact DC therebetween may be respectively connected to different active regions AC from among the plurality of active regions AC. In some implementations, the direct contact DC may include Si, Ge, W, WN, Co, Ni, Al, Mo, Ru, Ti, TiN, Ta, TaN, Cu, or a combination thereof. For example, the direct contact DC may include an epitaxial silicon layer.

Each of the plurality of bit lines BL may include a lower conductive layer 132, an intermediate conductive layer 134, and an upper conductive layer 136, which are formed in the stated order over the substrate 102. Although FIGS. 2 and 3 illustrate that each of the plurality of bit lines BL has a 3-layer structure, the present disclosure is not limited thereto. For example, each of the plurality of bit lines BL may have a structure in which a single layer, two layers, or 4 or more layers are stacked. In some implementations, the lower conductive layer 132 may include conductive polysilicon. Each of the intermediate conductive layer 134 and the upper conductive layer 136 may include TiN, TiSiN, W, tungsten silicide, or a combination thereof. For example, the intermediate conductive layer 134 may include TiN and/or TiSiN, and the upper conductive layer 136 may include W. An insulating capping pattern 138 may include a silicon nitride film.

Each of the plurality of conductive plugs 140P may have a column shape extending, on the substrate 102, in the vertical direction (the Z direction) along a space between each of the plurality of bit lines BL. The lower surface of each of the plurality of conductive plugs 140P may be in contact with the active region AC. A portion of each of the plurality of conductive plugs 140P may be at a lower level than the main surface 102M of the substrate 102. Each of the plurality of conductive plugs 140P may include doped polysilicon, a metal, a conductive metal nitride, or a combination thereof.

Each of the plurality of insulating fences 142 may have a column shape extending in the vertical direction (the Z direction) between each of the plurality of bit lines BL. Each of the plurality of insulating fences 142 may include a silicon nitride film.

Both sidewalls of each of the plurality of bit lines BL, the plurality of insulating capping patterns 138, and the plurality of direct contacts DC may be respectively covered by a plurality of insulating spacers 146. The plurality of insulating spacers 146 may be respectively arranged on both sidewalls of the plurality of bit lines BL and may extend lengthwise in the second horizontal direction (the Y direction) to be parallel to the plurality of bit lines BL. Each of the plurality of insulating spacers 146 may include an oxide film, a nitride film, an air spacer, or a combination thereof. As used herein, the term “air” may refer to a space including the atmosphere or including other gases that may be present during a fabrication process.

Each of the plurality of conductive plugs 140P may be apart from a bit line BL in the first horizontal direction (the X direction) with an insulating spacer 146 therebetween. Each of the plurality of insulating fences 142 may be apart from the bit line BL in the first horizontal direction (the X direction) with the insulating spacer 146 therebetween.

A metal silicide film 172 and a conductive landing pad LP may be sequentially formed in the stated order on the conductive plug 140P. The metal silicide film 172 and the conductive landing pad LP may be arranged to vertically overlap the conductive plug 140P. A plurality of metal silicide films 172 may each be arranged between the conductive plug 140P and the conductive landing pad LP and may each be apart from the bit line BL with the insulating spacer 146 therebetween. The metal silicide film 172 may include cobalt silicide, nickel silicide, or manganese silicide.

A plurality of conductive landing pads LP may each be connected to the conductive plug 140P via the metal silicide film 172. The plurality of conductive landing pads LP may extend from a space between each of the plurality of insulating capping patterns 138 to a space over each of the plurality of plurality of insulating capping patterns 138 to vertically overlap portions of the plurality of bit lines BL. Each of the plurality of conductive landing pads LP may include a conductive barrier film 174 and a conductive layer 176. The conductive barrier film 174 may include Ti, TiN, or a combination thereof. The conductive layer 176 may include a metal, a metal nitride, conductive polysilicon, or a combination thereof. For example, the conductive layer 176 may include tungsten (W).

The plurality of conductive landing pads LP may have a plurality of island pattern shapes when viewed in a plane (the X-Y plane). The plurality of conductive landing pads LP may be electrically insulated from each other by an insulating film 180 filling an insulating space 180S therearound. The insulating film 180 may include a silicon nitride film, a silicon oxide film, or a combination thereof.

In the integrated circuit device 100 shown in FIGS. 2 to 5, each of the plurality of metal-containing word lines 122 may be configured to have a structure including a single metal-containing film and to provide dual work functions due to the interface dipole layer DPL arranged along the interface between the second local region 123B of the metal oxide dielectric film 123 and the silicon oxide dielectric film 120. Therefore, the resistance in each of the plurality of metal-containing word lines 122 may be reduced, and the integrated circuit device 100 may have improved refresh characteristics and stable electrical characteristics by suppressing an increase in GIDL current and preventing the deterioration of data retention time.

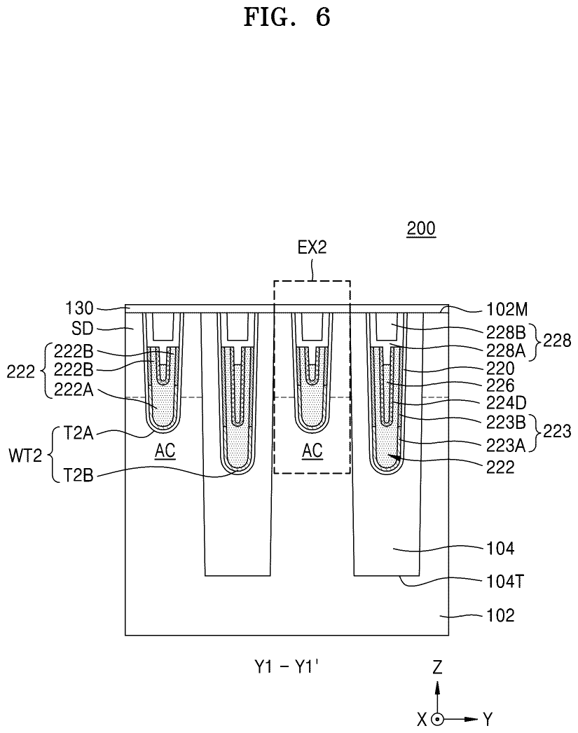

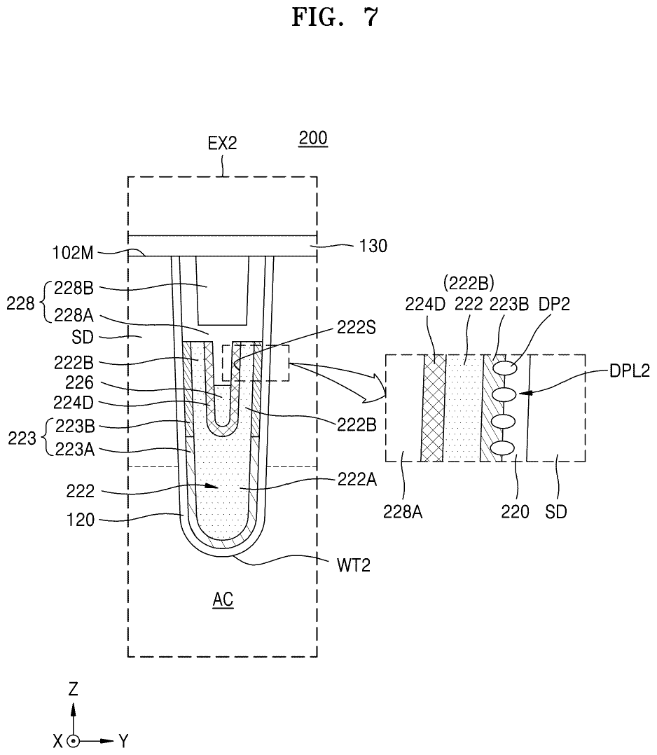

FIG. 6 is a cross-sectional view illustrating an integrated circuit device 200 according to some implementations. FIG. 6 illustrates a cross-sectional configuration of some components in a portion of the integrated circuit device 200, the portion corresponding to a cross-section taken along the line Y1-Y1′ of FIG. 1. FIG. 7 is an enlarged cross-sectional view of a region EX2 of FIG. 6. In FIGS. 6 and 7, the same reference numerals as in FIGS. 1 to 5 respectively denote the same members, and here, repeated descriptions thereof are omitted.

Referring to FIGS. 6 and 7, the integrated circuit device 200 has substantially the same configuration as the integrated circuit device 100 described with reference to FIGS. 1 to 5. However, in the integrated circuit device 200, a plurality of word line trenches WT2 may be formed in the substrate 102 to extend in the first horizontal direction (the X direction) to be parallel to each other. Each of the plurality of word line trenches WT2 may have a line shape extending lengthwise in the first horizontal direction (the X direction) across the plurality of active regions AC and the device isolation film 104. Each of the plurality of word line trenches WT2 may have a width in the second horizontal direction (the Y direction), the width gradually decreasing away from the main surface 102M of the substrate 102 in the vertical direction (the Z direction). A more specific configuration of a cross-sectional shape of the word line trench WT2 is substantially the same as that of each of the plurality of word line trenches WT described with reference to FIGS. 2, 4, and 5.

The inside of each of the plurality of word line trenches WT2 may be filled with a silicon oxide dielectric film 220, a metal-containing word line 222, a metal oxide dielectric film 223, a doped silicon layer 224D, an additional electrode layer 226, and an insulating capping pattern 228. The metal-containing word line 222 may correspond to the word line WL of FIG. 1.

The metal oxide dielectric film 223 may include a high-k film having a dielectric constant higher than that of a silicon oxide film. The high-k film may include a metal oxide. In some implementations, the metal oxide dielectric film 223 may include a titanium oxide film. The metal oxide dielectric film 223 may include a first local region 223A and a second local region 223B, which respectively have different dopant contents. In the metal oxide dielectric film 223, the first local region 223A is farther from the main surface 102M of the substrate 102 than the second local region 223B, and the second local region 223B is closer to the main surface 102M of the substrate 102 and the entrance of the word line trench WT2 than the first local region 223A. In the metal oxide dielectric film 223, a dopant content ratio in the second local region 223B may be greater than a dopant content ratio in the first local region 223A. The second local region 223B of the metal oxide dielectric film 223 may include a dopant selected from phosphorus (P), boron (B), arsenic (As), germanium (Ge), and a combination thereof. A more detailed configuration of the metal oxide dielectric film 223 is substantially the same as that of the metal oxide dielectric film 123 described with reference to FIGS. 2, 4, and 5.

The metal-containing word line 222 may include a metal-containing film. The metal-containing film may include a conductive metal nitride film. For example, the metal-containing film may include, but is not limited to, a TiN film. The metal-containing word line 222 may be arranged on the metal oxide dielectric film 223 to fill a lower space of the word line trench WT2, which is a portion of the word line trench WT2, and may extend lengthwise in the first horizontal direction (the X direction). The metal-containing word line 222 is apart from the silicon oxide dielectric film 220 with each of the first local region 223A and the second local region 223B of the metal oxide dielectric film 223 therebetween.

The metal-containing word line 222 may include a lower electrode portion 222A and two upper branch electrode portions 222B integrally connected to the lower electrode portion 222A and branched from the lower electrode portion 222A toward the main surface 102M of the substrate 102. The lower electrode portion 222A may be in contact with the first local region 223A of the metal oxide dielectric film 223, and each of the two upper branch electrode portions 222B may be in contact with the second local region 223B of the metal oxide dielectric film 223.

In each of a plurality of metal-containing word lines 222, the lower electrode portion 222A may have a plug shape having no space therein. Two upper branch electrode portions 222B constituting one metal-containing word line 222 may be arranged in the word line trench WT2 and may extend upward in the vertical direction (the Z direction) from the lower electrode portion 222A to define, together with the lower electrode portion 222A, an upper internal space 222S.

The doped silicon layer 224D may be arranged in the word line trench WT2 to fill a portion of the upper internal space 222S. The doped silicon layer 224D may have an approximately U-like cross-sectional shape in the upper internal space 222S. In the upper internal space 222S, the doped silicon layer 224D may be in contact with the metal-containing word line 222. The doped silicon layer 224D may be located apart from the second local region 223B of the metal oxide dielectric film 223 with an upper branch electrode portion 222B of the metal-containing word line 222 therebetween to contact the upper branch electrode portion 222B.

The doped silicon layer 224D may cover the surface of the metal-containing word line 222 with a substantially uniform thickness. In the upper internal space 222S, the doped silicon layer 224D may have a U-like cross-sectional shape having a gradually increasing width in the second horizontal direction (the Y direction) away from the lower electrode portion 222A in the vertical direction (the Z direction). The doped silicon layer 224D may include a portion facing the second local region 223B of the metal oxide dielectric film 223 in the second horizontal direction (the Y direction).

The doped silicon layer 224D may include doped amorphous silicon. The doped silicon layer 224D may include a dopant including the same element as a dopant element in the second local region 223B of the metal oxide dielectric film 223. In some implementations, the doped silicon layer 224D may include a dopant selected from phosphorus (P), boron (B), arsenic (As), germanium (Ge), and a combination thereof.

As shown in FIG. 7, an interface dipole layer DPL2 may be arranged between the second local region 223B of the metal oxide dielectric film 223 and the silicon oxide dielectric film 220. The interface dipole layer DPL2 may include a plurality of dipoles DP2 arranged along an interface between the second local region 223B of the metal oxide dielectric film 223 and the silicon oxide dielectric film 220. A more detailed configuration of the interface dipole layer DPL2 is substantially the same as that of the interface dipole layer DPL described with reference to FIG. 5.

Because the interface dipole layer DPL2 is arranged between the second local region 223B of the metal oxide dielectric film 223 and the silicon oxide dielectric film 220, a work function may be locally modulated by the interface dipole layer DPL2 in a BCAT structure that includes the metal-containing word line 222 including a single metal-containing film, and thus, a dual-gate transistor structure may be obtained.

The additional electrode layer 226 may be arranged on the doped silicon layer 224D in the upper internal space 222S. The additional electrode layer 226 may be located in an internal space defined by the doped silicon layer 224D having an approximately U-like cross-sectional shape. The additional electrode layer 226 may be arranged in the internal space, which is defined by the doped silicon layer 224D, to contact the doped silicon layer 224D. The additional electrode layer 226 may be apart from each of the lower electrode portion 222A and the two upper branch electrode portions 222B with the doped silicon layer 224D therebetween. The additional electrode layer 226 may include the same material as the constituent material of the metal-containing word line 222.

In the vertical direction (the Z direction), a vertical level (or distance) of the upper surface of the additional electrode layer 226 may be farther from the entrance (e.g., the upper surface) of the word line trench WT2 than a vertical level of the upper surface of each of the lower electrode portion 222A and the two upper branch electrode portions 222B of the metal-containing word line 222. The upper surface of the two upper branch electrode portions 222B and the upper surface of the doped silicon layer 224D can be between the upper surface of the additional electrode layer 226 and the upper surface of the word line trench WT2 along a vertical direction (e.g., Z direction). The entrance (e.g., the upper surface) of the word line trench WT2 can be aligned with the main surface 102M of the substrate 102. The upper surface of the two upper branch electrode portions 222B can be aligned with the upper surface of the doped silicon layer 224D.

The integrated circuit device 200 according to the present disclosure includes the interface dipole layer DPL2 arranged along the interface between the second local region 223B of the metal oxide dielectric film 223 and the silicon oxide dielectric film 220. The interface dipole layer DPL2 may locally modulate a work function such that an effective work function value of the metal-containing word line 222 including a single metal-containing film decreases. Therefore, a flat-band voltage may be reduced by the interface dipole layer DPL2, an increase in GIDL current may be suppressed, and a threshold voltage of a transistor including the metal-containing word line 222 may be precisely controlled, thereby preventing the deterioration of data retention time and improving refresh characteristics.

An insulating capping pattern 228 may fill an upper space of the word line trench WT2. The insulating capping pattern 228 may be arranged in the word line trench WT2 to cover the upper surface of each of the metal-containing word line 222, the second local region 223B of the metal oxide dielectric film 223, the doped silicon layer 224D, and the additional electrode layer 226. The insulating capping pattern 228 may include a first portion, which is located outside the upper internal space 222S, and a second portion, which is integrally connected to the first portion and is located inside the upper inner space 222S. The first portion of the insulating capping pattern 228 may be arranged outside the upper internal space 222S to contact the upper surface of the upper branch electrode portion 222B of the metal-containing word line 222, the upper surface of the second local region 223B of the metal oxide dielectric film 223, and the upper surface of the doped silicon layer 224D. The second portion of the insulating capping pattern 228 may protrude toward the additional electrode layer 226 to fill a portion of the internal space defined by the doped silicon layer 224D and may be arranged in the internal space to contact each of the doped silicon layer 224D and the additional electrode layer 226.

The insulating capping pattern 228 may include an insulating capping liner 228A and an insulating capping plug 228B. In the upper internal space 222S, the insulating capping liner 228A may be in contact with each of the silicon oxide dielectric film 220, the metal-containing word line 222, the second local region 223B of the metal oxide dielectric film 223, the doped silicon layer 224D, and the additional electrode layer 226. In the upper internal space 222S, the insulating capping plug 228B may be apart from each of the silicon oxide dielectric film 220, the metal-containing word line 222, the second local region 223B of the metal oxide dielectric film 223, the doped silicon layer 224D, and the additional electrode layer 226 with the insulating capping liner 228A therebetween. In some implementations, the insulating capping liner 228A may include a silicon oxide film and the insulating capping plug 228B may include a silicon nitride film, but the present disclosure is not limited thereto.

The interface dipole layer DPL2, which is arranged along the interface between the second local region 223B of the metal oxide dielectric film 223 and the silicon oxide dielectric film 220, may face a pair of source/drain regions SD respectively located on both sides of the silicon oxide dielectric film 220 based on the second horizontal direction (the Y direction). A work function in the upper branch electrode portion 222B, which is an upper portion of the metal-containing word line 222, may be modulated by the interface dipole layer DPL2, and thus, may be less than a work function in the lower electrode portion 222A. Therefore, the metal-containing word line 222 may have a dual-work function structure. The dual-work function structure is a result obtained because, in a structure in which each of the first local region 223A and the second local region 223B of the metal oxide dielectric film 223 surrounding the metal-containing word line 222 is in contact with the silicon oxide dielectric film 220, there is no dipole at the interface between the first local region 223A and the silicon oxide dielectric film 220 or there are dipoles in an ignorable amount not substantially affecting the work function of the metal-containing word line 222 even though there are dipoles at the interface therebetween, and there is the interface dipole layer DPL2, which includes a plurality of dipoles in a sufficient amount to modulate the work function of the metal-containing word line 222, at the interface between the second local region 223B and the silicon oxide dielectric film 220.

In each of the plurality of metal-containing word lines 222, the upper branch electrode portion 222B having a relatively low work function due to the interface dipole layer DPL2 may be arranged on the lower electrode portion 222A having a relatively high work function in the metal-containing word line 222, and thus, the upper branch electrode portion 222B having a relatively low work function may be arranged closer to the source/drain region SD. Therefore, the upper branch electrode portion 222B of the metal-containing word line 222 may have a structure in which the area overlapping the source/drain region SD including an impurity region in the second horizontal direction (the Y direction) is larger than that in the lower electrode portion 222A. Therefore, in the integrated circuit device 200, an increase in GIDL current may be suppressed, and the deterioration of data retention time may be prevented, thereby improving refresh characteristics. In addition, because the lower electrode portion 222A in each of the plurality of metal-containing word lines 222 of the integrated circuit device 200 has a relatively high work function, the resistance in the metal-containing word line 222 may be reduced, and a threshold voltage targeted by a transistor may be precisely controlled. Therefore, the integrated circuit device 200 may secure stable electrical characteristics.

In addition, each of the plurality of metal-containing word lines 222 of the integrated circuit device 200 may include only a metal-containing structure and may not include a material having relatively large resistance, such as polysilicon. Therefore, the volume occupied by a metal in each of the plurality of metal-containing word lines 222 may be increased, thereby reducing the resistance in each of the plurality of metal-containing word lines 222.

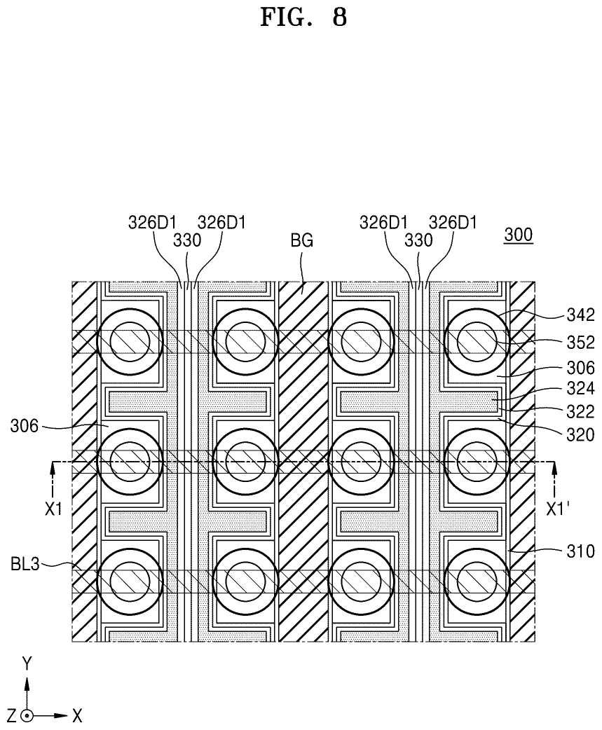

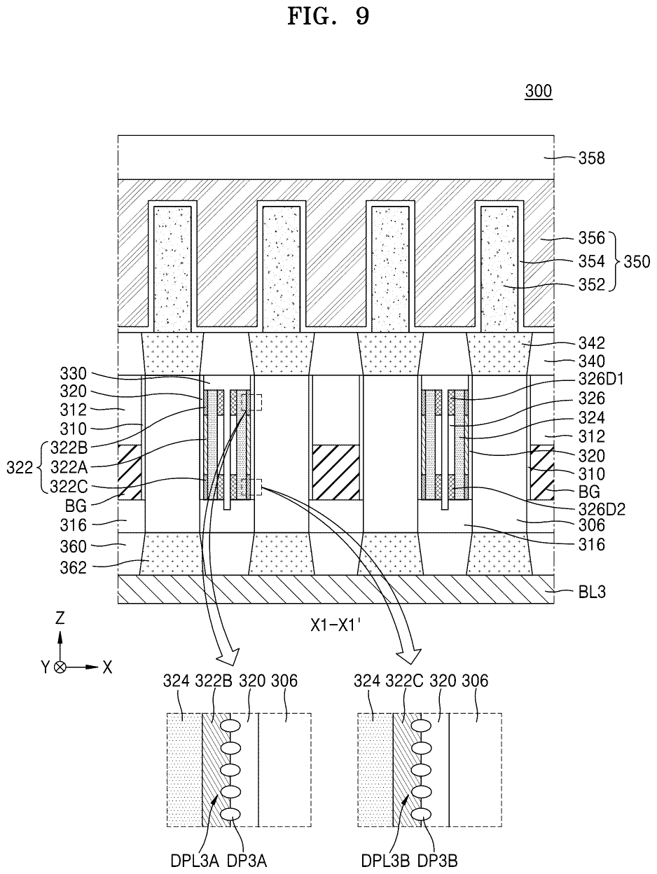

FIG. 8 is a planar layout diagram illustrating some components of an integrated circuit device 300 according to some implementations. FIG. 9 is a cross-sectional view of the integrated circuit device 300, taken along a line X1-X1′ of FIG. 8.

Referring to FIGS. 8 and 9, the integrated circuit device 300 may include a plurality of conductive lines BL3, which extend lengthwise in the first horizontal direction (the X direction) and are repeatedly arranged apart from each other in the second horizontal direction (the Y direction) that is perpendicular to the first horizontal direction (the X direction). In the integrated circuit device 300, each of the plurality of conductive lines BL3 may constitute a bit line.

A plurality of active regions 306 may be arranged over each of the plurality of conductive lines BL3. The plurality of active regions 306 may be repeatedly arranged apart from each other in the first horizontal direction (the X direction) and the second horizontal direction (the Y direction). In the integrated circuit device 300, each of the plurality of active regions 306 may be used as a channel region. A plurality of contact plugs 342 may be respectively arranged on the plurality of active regions 306. Each of the plurality of active regions 306 may have one end connected to one contact plug 362 selected from a plurality of contact plugs 362, and the other end connected to one contact plug 342 selected from the plurality of contact plugs 342. The one end of each of the plurality of active regions 306 may be configured to be connected to one conductive line BL3, which is selected from the plurality of conductive lines BL3, via the contact plug 362. The other end of each of the plurality of active regions 306 may be configured to be connected to one lower electrode 352 selected from a plurality of lower electrodes 352, which are included in a capacitor structure 350, via one contact plug 342 selected from the plurality of contact plugs 342.

Each of the plurality of conductive lines BL3 may include a metal, a conductive metal nitride, a metal silicide, doped polysilicon, or a combination thereof. For example, each of the plurality of conductive lines BL3 may include Ti, TiN, Ta, TaN, Mo, Ru, W, WN, Co, Ni, TiSi, TiSiN, WSi, WSiN, TaSi, TaSiN, RuTiN, CoSi, NiSi, doped polysilicon, or a combination thereof. In some implementations, each of the plurality of conductive lines BL3 may include a first conductive line including doped polysilicon, a second conductive line including a metal silicide, and a third conductive line including a metal.

The plurality of contact plugs 342 may be arranged in a matrix to be apart from each other in the first horizontal direction (the X direction) and the second horizontal direction (the Y direction), and the plurality of contact plugs 362 may also be arranged in a matrix to be apart from each other in the first horizontal direction (the X direction) and the second horizontal direction (the Y direction). The plurality of contact plugs 342 may be respectively connected to the plurality of active regions 306, and the plurality of contact plugs 362 may also be respectively connected to the plurality of active regions 306. The plurality of contact plugs 342 and the plurality of contact plugs 362 may each include a metal, a conductive metal nitride, a metal silicide, doped polysilicon, or a combination thereof. For example, the plurality of contact plugs 342 and the plurality of contact plugs 362 may each include Ti, TiN, Ta, TaN, Mo, Ru, W, WN, Co, Ni, TiSi, TiSiN, WSi, WSiN, TaSi, TaSiN, RuTiN, CoSi, NiSi, doped polysilicon, or a combination thereof. In some implementations, each of the plurality of contact plugs 342 and the plurality of contact plugs 362 may include a first conductive pattern including doped polysilicon, a second conductive pattern including a metal silicide, and a third conductive pattern including a metal.

As shown in FIG. 8, the plurality of active regions 306 may include a first group of active regions 306, which are arranged in a line in the first horizontal direction (the X direction) and apart from each other in the first horizontal direction (the X direction), and a second group of active regions 306, which are arranged in a line in the second horizontal direction (the Y direction) and apart from each other in the second horizontal direction (the Y direction). Each of the plurality of contact plugs 342 may be in contact with an active region 306 selected from the plurality of active regions 306 through an interlayer dielectric 340. Each of the plurality of contact plugs 362 may be in contact with an active region 306 selected from the plurality of active regions 306 through an interlayer dielectric 360. Each of the interlayer dielectrics 340 and 360 may include a silicon oxide film, a silicon nitride film, or a combination thereof.

In some implementations, each of the plurality of active regions 306 may include silicon, for example, monocrystalline silicon, polycrystalline silicon, or amorphous silicon. In some implementations, each of the plurality of active regions 306 may include at least one selected from Ge, SiGe, SiC, GaAs, InAs, and InP. In some implementations, an active region 306 may include a conductive region, for example, an impurity-doped well, or an impurity-doped structure.

A plurality of back gate electrodes BG and a plurality of metal-containing word lines 324 may be arranged between the plurality of conductive lines BL3 and the capacitor structure 350. A metal-containing word line 324 may function as a word line. The plurality of back gate electrodes BG and the plurality of metal-containing word lines 324 may each extend lengthwise in the second horizontal direction (the Y direction). The plurality of back gate electrodes BG may be apart from each other in the first horizontal direction (the X direction), and the plurality of metal-containing word lines 324 may be apart from each other in the first horizontal direction (the X direction).

In a plurality of back gate electrodes BG and a plurality of metal-containing word lines 324, which are aligned in a line in the first horizontal direction (the X direction) over one conductive line BL3, one back gate electrode BG and a pair of metal-containing word lines 324 may be alternately arranged, and the one back gate electrode BG may be apart from the pair of metal-containing word lines 324 with one active region 306 therebetween. That is, a pair of metal-containing word lines 324 adjacent to each other, among the plurality of metal-containing word lines 324, may be arranged between each of the plurality of back gate electrodes BG.

Each of the plurality of back gate electrodes BG may include a metal, a conductive metal nitride, doped polysilicon, or a combination thereof. For example, each of the plurality of back gate electrodes BG may include, but is not limited to, Ti, TiN, Ta, TaN, Mo, Ru, W, WN, TiSiN, WSiN, doped polysilicon, or a combination thereof. Each of the plurality of metal-containing word lines 324 may include a metal-containing film. The metal-containing film may include a metal nitride film. For example, the metal-containing film may include, but is not limited to, a TiN film.

A silicon oxide dielectric film 320 and a metal oxide dielectric film 322 may be arranged between the metal-containing word line 324 and the active region 306 adjacent to the metal-containing word line 324. The silicon oxide dielectric film 320 may have one sidewall contacting the metal oxide dielectric film 322 and the other sidewall contacting the active region 306. The metal oxide dielectric film 322 may have one sidewall contacting the silicon oxide dielectric film 320 and the other sidewall contacting the metal-containing word line 324.

Each of a plurality of silicon oxide dielectric films 320, which are arranged between the plurality of conductive lines BL3 and the capacitor structure 350, may be arranged between an active region 306 selected from the plurality of active regions 306 and the metal-containing word line 324 and may be in contact with a sidewall of the selected active region 306. Each of the plurality of silicon oxide dielectric films 320 may include a silicon oxide film.

Each of a plurality of metal oxide dielectric films 322, which are arranged between the plurality of conductive lines BL3 and the capacitor structure 350, may be arranged between a silicon oxide dielectric film 320 adjacent thereto and a metal-containing word line 324 adjacent thereto. Each of the plurality of metal oxide dielectric films 322 may include a high-k film having a dielectric constant higher than that of a silicon oxide film. The high-k film may include a metal oxide. In some implementations, each of the plurality of metal oxide dielectric films 322 may include a titanium oxide film.

Each of the plurality of metal oxide dielectric films 322 may include a first local region 322A, which is in contact with a first portion of the silicon oxide dielectric film 320, and an upper second local region 322B and a lower second local region 322C, which are respectively in contact with a second portion and a third portion of the silicon oxide dielectric film 320, the second portion and the third portion being adjacent to the first portion of the silicon oxide dielectric film 320 and apart from each other in the vertical direction (the Z direction) with the first portion therebetween. The upper second local region 322B and the lower second local region 322C may be apart from each other in the vertical direction (the Z direction) with the first local region 322A therebetween.

In the metal oxide dielectric film 322, a dopant content ratio in each of the upper second local region 322B and the lower second local region 322C may be greater than a dopant content ratio in the first local region 322A. The dopant content ratio in the lower second local region 322C may be equal to or different from the dopant content ratio in the upper second local region 322B. The upper second local region 322B and the lower second local region 322C of the metal oxide dielectric film 322 may each include a dopant selected from phosphorus (P), boron (B), arsenic (As), germanium (Ge), and a combination thereof. In some implementations, the dopant content ratio in each of the upper second local region 322B and the lower second local region 322C of the metal oxide dielectric film 322 may be constant depending on positions therein. In some implementations, the dopant content ratio in each of the upper second local region 322B and the lower second local region 322C of the metal oxide dielectric film 322 may gradually decrease toward the first local region 322A in the vertical direction (the Z direction). The first local region 322A of the metal oxide dielectric film 322 may include no dopant or may include a dopant in an amount equal to or less than a detection limit even though including the dopant.

One sidewall of the metal-containing word line 324 may be in contact with each of the first local region 322A, the upper second local region 322B, and the lower second local region 322C of the metal oxide dielectric film 322 adjacent thereto. The other sidewall of the metal-containing word line 324 may be in contact with a silicon layer 326 and doped silicon layers 326D1 and 326D2. The silicon layer 326 and the doped silicon layers 326D1 and 326D2 may have an integrally connected structure. The doped silicon layers 326D1 and 326D2 may be apart from each other with the silicon layer 326 therebetween. The doped silicon layer 326D1 may be apart from the upper second local region 322B of the metal oxide dielectric film 322 in the first horizontal direction (the X direction) with the metal-containing word line 324 therebetween and may face the upper second local region 322B in the first horizontal direction (the X direction). The doped silicon layer 326D2 may be apart from the lower second local region 322C of the metal oxide dielectric film 322 in the first horizontal direction (the X direction) with the metal-containing word line 324 therebetween and may face the lower second local region 322C in the first horizontal direction (the X direction).

The silicon layer 326 may include undoped amorphous silicon. The doped silicon layers 326D1 and 326D2 may each include doped amorphous silicon. Each of the doped silicon layers 326D1 and 326D2 may include a dopant including the same element as a dopant element in each of the upper second local region 322B and the lower second local region 322C of the metal oxide dielectric film 322. In some implementations, each of the doped silicon layers 326D1 and 326D2 may include a dopant selected from phosphorus (P), boron (B), arsenic (As), germanium (Ge), and a combination thereof.

A first interface dipole layer DPL3A, which includes a plurality of first dipoles DP3A arranged along an interface between the upper second local region 322B and the silicon oxide dielectric film 320, may be arranged between the upper second local region 322B of the metal oxide dielectric film 322 and the silicon oxide dielectric film 320. A second interface dipole layer DPL3B, which includes a plurality of second dipoles DP3B arranged along an interface between the lower second local region 322C and the silicon oxide dielectric film 320, may be arranged between the lower second local region 322C of the metal oxide dielectric film 322 and the silicon oxide dielectric film 320. Between the first local region 322A of the metal oxide dielectric film 322 and the silicon oxide dielectric film 320, there may be no dipole or, even though there are dipoles, there may be dipoles in an ignorable amount not substantially affecting the work function of the metal-containing word line 324.

The first interface dipole layer DPL3A may face the doped silicon layer 326D1 in the first horizontal direction (the X direction). The second interface dipole layer DPL3B may face the doped silicon layer 326D2 in the first horizontal direction (the X direction). The first interface dipole layer DPL3A may include a plurality of dipoles formed by interactions between dopant atoms derived from the upper second local region 322B of the metal oxide dielectric film 322 and oxygen atoms derived from the silicon oxide dielectric film 320. The second interface dipole layer DPL3B may include a plurality of dipoles formed by interactions between dopant atoms derived from the lower second local region 322C of the metal oxide dielectric film 322 and oxygen atoms derived from the silicon oxide dielectric film 320.

For example, when each of the upper second local region 322B and the lower second local region 322C of the metal oxide dielectric film 322 includes a titanium oxide film doped with phosphorus (P) atoms and the silicon oxide dielectric film 320 includes a silicon oxide film, each of the first interface dipole layer DPL3A and the second interface dipole layer DPL3B may include a plurality of dipoles formed by dipole bonding between phosphorus (P) atoms derived from each of the upper second local region 322B and the lower second local region 322C of the metal oxide dielectric film 322 and oxygen atoms derived from the silicon oxide dielectric film 320. In each of the upper second local region 322B and the lower second local region 322C of the metal oxide dielectric film 322, the density of dipoles in each of the first interface dipole layer DPL3A and the second interface dipole layer DPL3B may decrease toward the first local region 322A of the metal oxide dielectric film 322.

Because the first interface dipole layer DPL3A is arranged between the upper second local region 322B of the metal oxide dielectric film 322 and the silicon oxide dielectric film 320 and the second interface dipole layer DPL3B is arranged between the lower second local region 322C of the metal oxide dielectric film 322 and the silicon oxide dielectric film 320, a work function may be locally modulated by the first interface dipole layer DPL3A and the second interface dipole layer DPL3B in a vertical channel transistor that includes the metal-containing word line 324 including a single metal-containing film, thereby obtaining a dual-gate transistor structure.

Each of the plurality of back gate electrodes BG may extend lengthwise in the second horizontal direction (the Y direction) between two active regions 306 adjacent to each other in the first horizontal direction (the X direction). Each of the plurality of back gate electrodes BG may be arranged apart from the plurality of contact plugs 342 and the plurality of contact plugs 362. As shown in FIG. 9, each of the plurality of back gate electrodes BG may include a pair of sidewalls respectively facing active regions 306, one end facing the capacitor structure 350, and the other end facing a conductive line BL3.

The integrated circuit device 300 may include a plurality of back gate dielectric films 310 respectively covering the surfaces of each of the plurality of back gate electrodes BG. Each of the plurality of back gate dielectric films 310 may be arranged between a back gate electrode BG and an active region 306 adjacent to the back gate electrode BG. The plurality of back gate dielectric films 310 may be respectively in contact with a pair of active regions 306 adjacent to each other from among the plurality of active regions 306. A back gate dielectric film 310 may be arranged between the pair of active regions 306 adjacent to each other to cover the back gate electrode BG. In the vertical direction (the Z direction), the length of the back gate dielectric film 310 may be greater than the length of the back gate electrode BG.

Each of the back gate dielectric films 310 may include a silicon oxide film, a high-k film, or a combination thereof. The high-k film refers to a film having a dielectric constant higher than that of a silicon oxide film. In some implementations, each of the back gate dielectric films 310 may include at least one material selected from silicon oxide, hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (SBT), bismuth iron oxide (BFO), strontium titanium oxide (SrTiO), yttrium oxide (YO), aluminum oxide (AlO), and lead scandium tantalum oxide (PbScTaO).

The one end, which faces the capacitor structure 350, of the back gate electrode BG may be covered by a first capping insulating pattern 312, and the other end, which faces the conductive line BL3, of the back gate electrode BG may be covered by a second capping insulating pattern 316. The first capping insulating pattern 312, the back gate electrode BG, and the second capping insulating pattern 316 may be arranged to overlap each other in the vertical direction (the Z direction). Each of the first capping insulating pattern 312 and the second capping insulating pattern 316 may include a silicon oxide film, a silicon nitride film, or a combination thereof. In some implementations, the first capping insulating pattern 312 and the second capping insulating pattern 316 may respectively include different materials. For example, one of the first capping insulating pattern 312 and the second capping insulating pattern 316 may include a silicon oxide film, and the other one may include a silicon nitride film. In some implementations, the first capping insulating pattern 312 and the second capping insulating pattern 316 may include the same material. For example, the first capping insulating pattern 312 and the second capping insulating pattern 316 may include the same material selected from a silicon oxide film and a silicon nitride film.

Each of the plurality of metal-containing word lines 324 may be arranged apart from the plurality of contact plugs 342 and the plurality of contact plugs 362 in the vertical direction (the Z direction). In the first horizontal direction (the X direction), a pair of metal-containing word lines 324 selected from the plurality of metal-containing word lines 324 may be arranged between each of the plurality of back gate electrodes BG. The pair of metal-containing word lines 324 may be apart from, in the first horizontal direction (the X direction), the back gate electrode BG adjacent thereto with one active region 306 therebetween.

An isolation insulating pattern 330 may be arranged between a pair of metal-containing word lines 324 that are arranged between a pair of active regions 306 adjacent to each other. The isolation insulating pattern 330 may include a portion arranged between the pair of metal-containing word lines 324 and a portion arranged between the interlayer dielectric 340 and the pair of metal-containing word lines 324. The second capping insulating pattern 316 may be arranged between the pair of metal-containing word lines 324 and the interlayer dielectric 360. The isolation insulating pattern 330, the pair of metal-containing word lines 324, and the second capping insulating pattern 316 may be arranged between the pair of active regions 306 adjacent to each other to overlap each other in the vertical direction (the Z direction).

Each of the isolation insulating pattern 330 and the second capping insulating pattern 316 may include a silicon oxide film, a silicon nitride film, or a combination thereof. In some implementations, the isolation insulating pattern 330 and the second capping insulating pattern 316 may respectively include the same or similar insulating materials. In some implementations, the isolation insulating pattern 330 and the second capping insulating pattern 316 may respectively include different insulating materials. For example, each of the isolation insulating pattern 330 and the second capping insulating pattern 316 may include, but is not limited to, a silicon nitride film.

The plurality of back gate electrodes BG, the plurality of metal-containing word lines 324, the plurality of active regions 306, the plurality of back gate dielectric films 310, the plurality of silicon oxide dielectric films 320, the plurality of metal oxide dielectric films 322, and a plurality of first and second interface dipole layers DPL3A and DPL3B, which are all arranged between the plurality of conductive lines BL3 and the capacitor structure 350, may constitute a plurality of vertical channel transistors.

The capacitor structure 350 may be arranged on the plurality of contact plugs 342 and the interlayer dielectric 340. The capacitor structure 350 may include a plurality of lower electrodes 352, a capacitor dielectric film 354 conformally covering the respective surfaces of the plurality of lower electrodes 352, and an upper electrode 356 covering the plurality of lower electrodes 352 with the capacitor dielectric film 354 therebetween. Each of the plurality of lower electrodes 352 may be connected to an active region 306 via a single contact plug 342 selected from the plurality of contact plugs 342.

According to the integrated circuit device 300 described with reference to FIGS. 8 and 9, even when components required to form a vertical channel transistor are arranged in a relatively narrow and long space due to the micronization and higher-integration of the integrated circuit device 300, a dual-gate transistor structure may be implemented in the vertical channel transistor, and thus, the integrated circuit device 300 may suppress an increase in GIDL current and may prevent the deterioration of data retention time, thereby improving refresh characteristics. In addition, each of the plurality of metal-containing word lines 324 of the integrated circuit device 300 may include only a metal-containing structure and may not include a material having relatively large resistance, such as polysilicon. Therefore, the volume occupied by a metal in each of the plurality of metal-containing word lines 324 may be increased, thereby reducing the resistance in each of the plurality of metal-containing word lines 324.

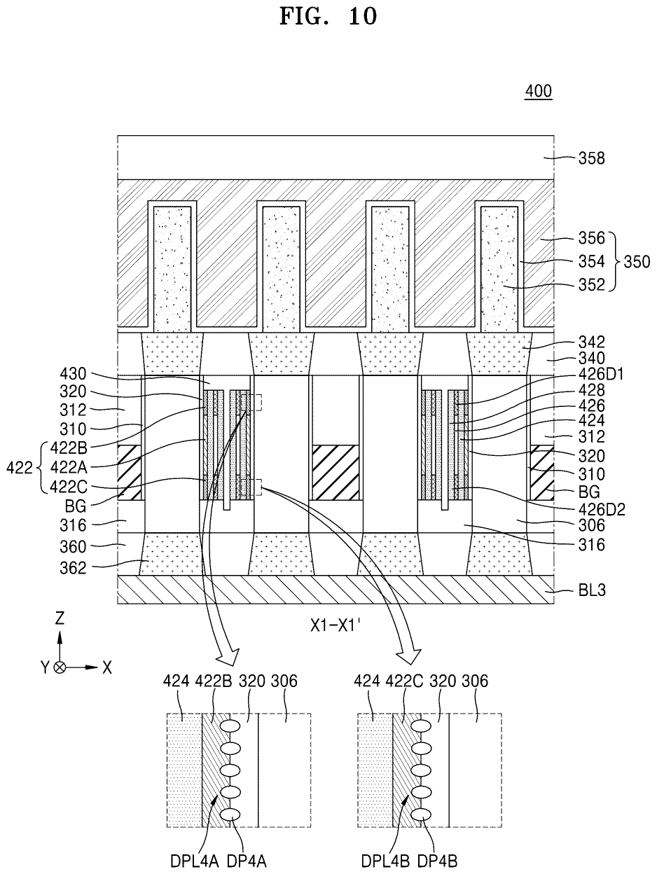

FIG. 10 is a cross-sectional view illustrating an integrated circuit device 400 according to some implementations. FIG. 10 illustrates some components in a portion of the integrated circuit device 400, the portion corresponding to a cross-section taken along a line X1-X1′ of FIG. 9. In FIG. 10, the same reference numerals as in FIGS. 8 and 9 respectively denote the same members, and here, repeated descriptions thereof are omitted.

Referring to FIG. 10, the integrated circuit device 400 has substantially the same configuration as the integrated circuit device 300 described with reference to FIGS. 8 and 9. The integrated circuit device 400 may include a metal oxide dielectric film 422, a metal-containing word line 424, a silicon layer 426, doped silicon layers 426D1 and 426D2, and an additional electrode layer 428, which are sequentially stacked in the stated order on a sidewall of the silicon oxide dielectric film 320. A detailed configuration of the metal-containing word line 424 is substantially the same as that of the metal-containing word line 324 described with reference to FIG. 9.

The metal oxide dielectric film 422 may have a substantially similar configuration to that of the metal oxide dielectric film 322 described with reference to FIG. 9. The metal oxide dielectric film 422 may have one sidewall contacting the silicon oxide dielectric film 320 and the other sidewall contacting the metal-containing word line 424. Each metal oxide dielectric film 422 may include a first local region 422A, which is in contact with a first portion of the silicon oxide dielectric film 320, and an upper second local region 422B and a lower second local region 422C, which are respectively in contact with a second portion and a third portion of the silicon oxide dielectric film 420, the second portion and the third portion being adjacent to the first portion of the silicon oxide dielectric film 320 and apart from each other in the vertical direction (the Z direction) with the first portion therebetween. The upper second local region 422B and the lower second local region 422C may be apart from each other in the vertical direction (the Z direction) with the first local region 422A therebetween. More detailed configurations of the first local region 422A, the upper second local region 422B, and the lower second local region 422C of the metal oxide dielectric film 422 are substantially similar to those of the first local region 322A, the upper second local region 322B, and the lower second local region 322C of the metal oxide dielectric film 322 described with reference to FIG. 9, respectively.

One sidewall of the metal-containing word line 424 may be in contact with each of the first local region 422A, the upper second local region 422B, and the lower second local region 422C of the metal oxide dielectric film 422 that is adjacent thereto. The other sidewall of the metal-containing word line 424 may be in contact with the silicon layer 426 and the doped silicon layers 426D1 and 426D2. The silicon layer 426 and the doped silicon layers 426D1 and 426D2 may have an integrally connected structure. The doped silicon layers 426D1 and 426D2 may be apart from each other with the silicon layer 426 therebetween. The doped silicon layer 426D1 may be apart from the upper second local region 422B of the metal oxide dielectric film 422 in the first horizontal direction (the X direction) with the metal-containing word line 424 therebetween and may face the upper second local region 422B in the first horizontal direction (the X direction). The doped silicon layer 426D2 may be apart from the lower second local region 422C of the metal oxide dielectric film 422 in the first horizontal direction (the X direction) with the metal-containing word line 424 therebetween and may face the lower second local region 422C in the first horizontal direction (the X direction). More detailed configurations of the silicon layer 426 and the doped silicon layers 426D1 and 426D2 are substantially the same as those of the silicon layer 326 and the doped silicon layers 326D1 and 326D2 described with reference to FIG. 9, respectively.

A first interface dipole layer DPL4A, which includes a plurality of first dipoles DP4A arranged along an interface between the upper second local region 422B and the silicon oxide dielectric film 320, may be arranged between the upper second local region 422B of the metal oxide dielectric film 422 and the silicon oxide dielectric film 320. A second interface dipole layer DPL4B, which includes a plurality of second dipoles DP4B arranged along an interface between the lower second local region 422C and the silicon oxide dielectric film 320, may be arranged between the lower second local region 422C of the metal oxide dielectric film 422 and the silicon oxide dielectric film 320. Between the first local region 422A of the metal oxide dielectric film 422 and the silicon oxide dielectric film 320, there may be no dipole or, even though there are dipoles, there may be dipoles in an ignorable amount not substantially affecting the work function of the metal-containing word line 424.

The first interface dipole layer DPL4A may face the doped silicon layer 426D1 in the first horizontal direction (the X direction). The second interface dipole layer DPL4B may face the doped silicon layer 426D2 in the first horizontal direction (the X direction). The first interface dipole layer DPL4A may include a plurality of dipoles formed by interactions between dopant atoms derived from the upper second local region 422B of the metal oxide dielectric film 422 and oxygen atoms derived from the silicon oxide dielectric film 320. The second interface dipole layer DPL4B may include a plurality of dipoles formed by interactions between dopant atoms derived from the lower second local region 422C of the metal oxide dielectric film 422 and oxygen atoms derived from the silicon oxide dielectric film 320.

For example, when each of the upper second local region 422B and the lower second local region 422C of the metal oxide dielectric film 422 includes a titanium oxide film doped with phosphorus (P) atoms and the silicon oxide dielectric film 320 includes a silicon oxide film, each of the first interface dipole layer DPL4A and the second interface dipole layer DPL4B may include a plurality of dipoles formed by dipole bonding between phosphorus (P) atoms derived from each of the upper second local region 422B and the lower second local region 422C of the metal oxide dielectric film 422 and oxygen atoms derived from the silicon oxide dielectric film 320. In each of the upper second local region 422B and the lower second local region 422C of the metal oxide dielectric film 422, the density of dipoles in each of the first interface dipole layer DPL4A and the second interface dipole layer DPL4B may decrease toward the first local region 422A of the metal oxide dielectric film 422.

Because the first interface dipole layer DPL4A is arranged between the upper second local region 422B of the metal oxide dielectric film 422 and the silicon oxide dielectric film 320 and the second interface dipole layer DPL4B is arranged between the lower second local region 422C of the metal oxide dielectric film 422 and the silicon oxide dielectric film 320, a work function may be locally modulated by the first interface dipole layer DPL4A and the second interface dipole layer DPL4B in a vertical channel transistor that includes the metal-containing word line 424 including a single metal-containing film, thereby obtaining a dual-gate transistor structure.

In the integrated circuit device 400, the additional electrode layer 428 may be apart from the metal-containing word line 424 in the first horizontal direction (the X direction) with the silicon layer 426 and the doped silicon layers 426D1 and 426D2 therebetween. The additional electrode layer 428 may extend parallel to the metal-containing word line 424. The additional electrode layer 428 may include the same material as the metal-containing word line 424. The additional electrode layer 428 may be in contact with the silicon layer 426 adjacent thereto and the doped silicon layers 426D1 and 426D2 adjacent thereto.

An isolation insulating pattern 430 may be arranged between a pair of additional electrode layers 428 that are arranged between a pair of active regions 306 adjacent to each other. The isolation insulating pattern 430 may include a portion arranged between the pair of additional electrode layers 428 and a portion arranged between the interlayer dielectric 340 and all of the pair of additional electrode layers 428 and a pair of metal-containing word lines 424 adjacent to the pair of additional electrode layers 428. A more detailed configuration of the isolation insulating pattern 430 is substantially the same as that of the isolation insulating pattern 330 described with reference to FIG. 9.

A plurality of metal-containing word lines 424, the plurality of active regions 306, the plurality of back gate dielectric films 310, the plurality of silicon oxide dielectric films 320, a plurality of metal oxide dielectric films 422, a plurality of additional electrode layers 428, a plurality of first and second interface dipole layers DPL4A and DPL4B, and the plurality of back gate electrodes BG, which are all arranged between the plurality of conductive lines BL3 and the capacitor structure 350, may constitute a plurality of vertical channel transistors.

According to the integrated circuit device 400 described with reference to FIG. 10, even when components required to form a vertical channel transistor are arranged in a relatively narrow and long space due to the micronization and higher-integration of the integrated circuit device 400, a dual-gate transistor structure may be implemented in the vertical channel transistor, and thus, the integrated circuit device 400 may suppress an increase in GIDL current and may prevent the deterioration of data retention time, thereby improving refresh characteristics. In addition, each of the plurality of metal-containing word lines 424 of the integrated circuit device 400 may include only a metal-containing structure and may not include a material having relatively large resistance, such as polysilicon. Therefore, the volume occupied by a metal in each of the plurality of metal-containing word lines 424 may be increased, thereby reducing the resistance in each of the plurality of metal-containing word lines 424.

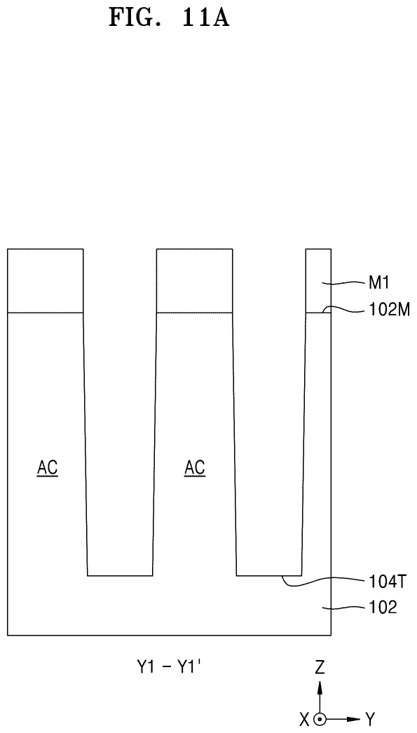

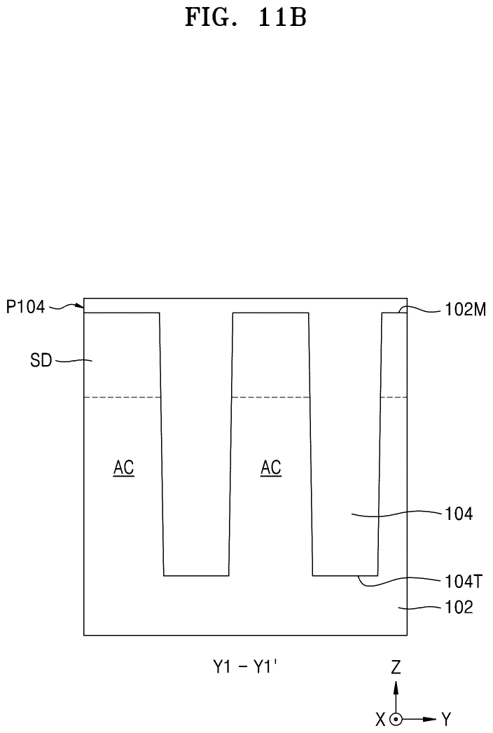

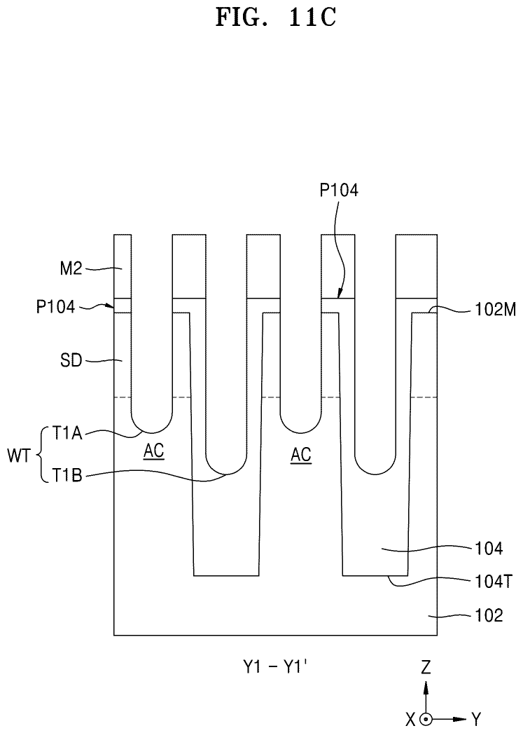

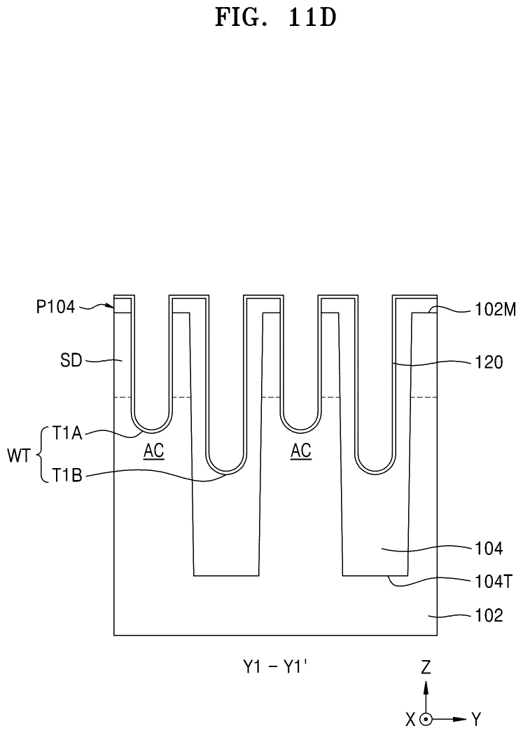

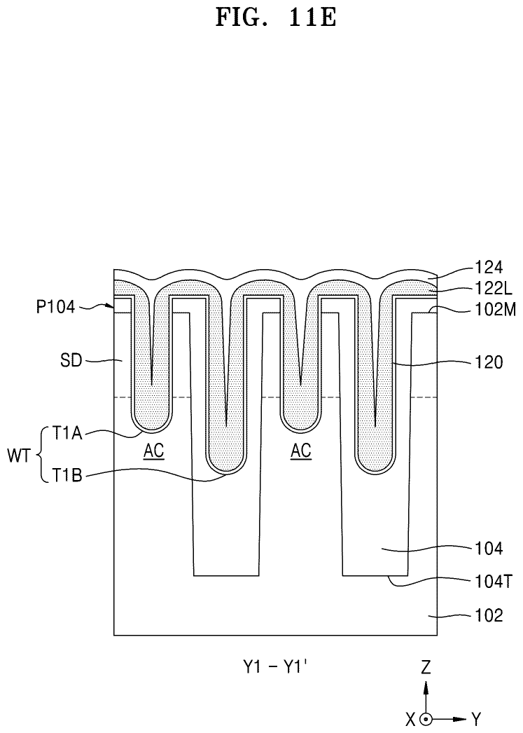

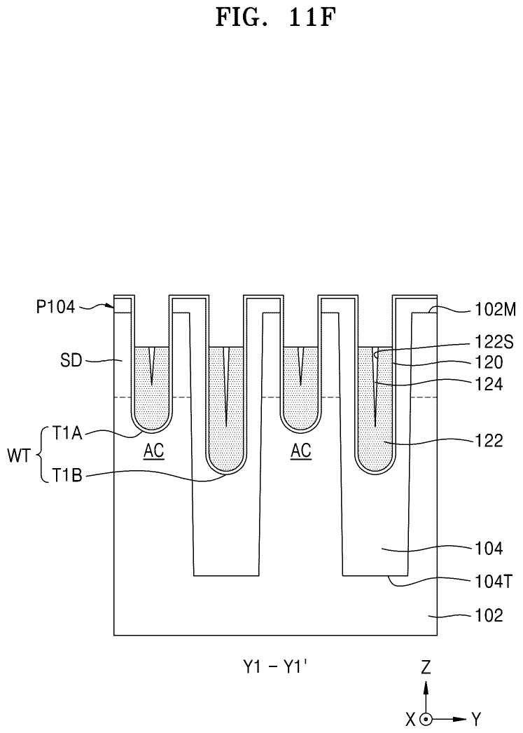

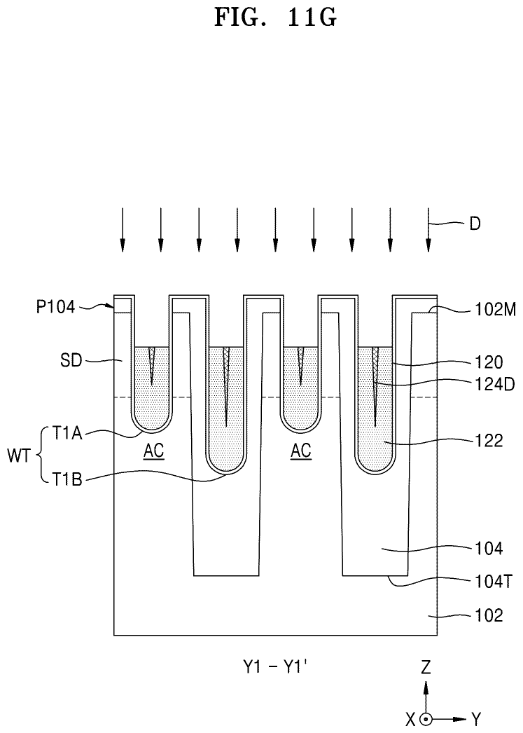

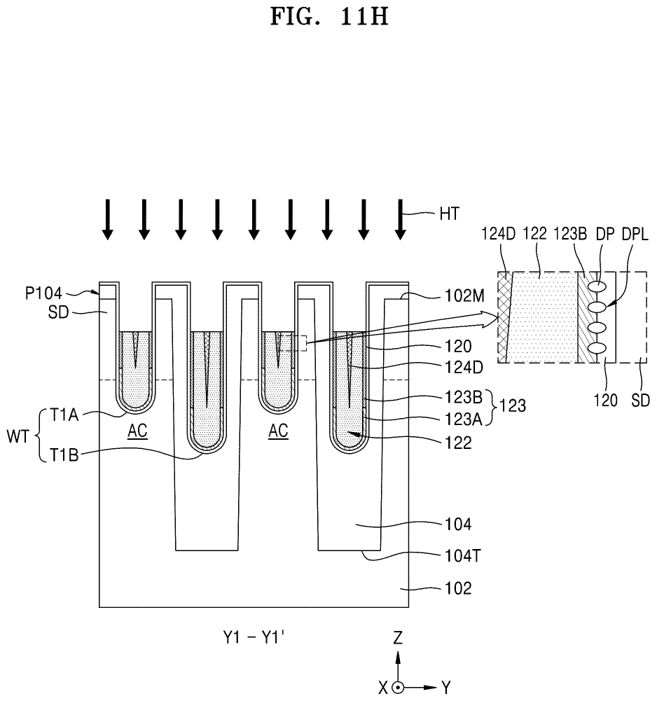

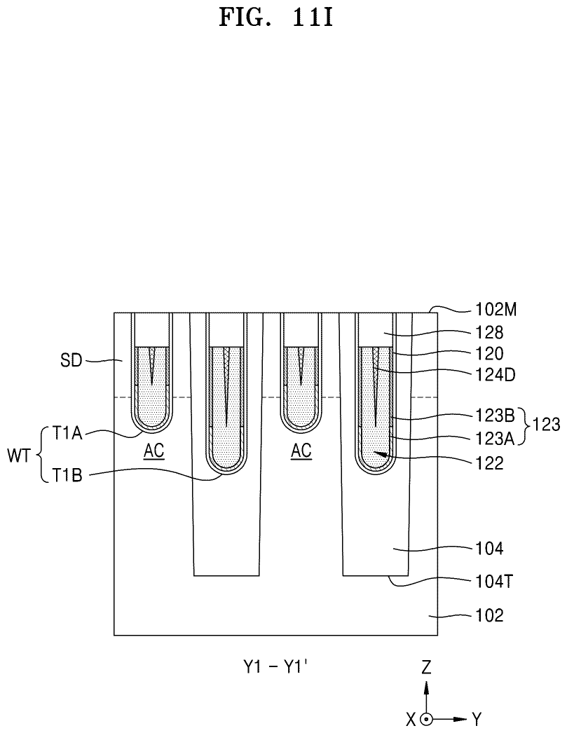

FIGS. 11A to 11I are cross-sectional views respectively illustrating a sequence of processes of a method of fabricating an integrated circuit device, according to implementations. FIGS. 11A to 11I each illustrate a cross-sectional configuration of a region corresponding to a cross-section taken along the line Y1-Y1′ of FIG. 1 according to the sequence of processes. An example of a method of fabricating the integrated circuit device 100 shown in FIGS. 1 to 5 is described with reference to FIGS. 11A to 11I. In FIGS. 11A to 11I, the same reference numerals as in FIGS. 1 to 5 respectively denote the same members, and here, repeated descriptions thereof are omitted.

Referring to FIG. 11A, a mask pattern M1 may be formed on the main surface 102M of the substrate 102, and the substrate 102 may be etched by using the mask pattern M1 as an etch mask, thereby forming a device isolation trench 104T. A plurality of active regions AC may be defined in the substrate 102 by the device isolation trench 104T. The mask pattern M1 may include a hardmask including an oxide film, polysilicon, or a combination thereof.

Referring to FIG. 11B, the mask pattern M1 may be removed from the resulting product of FIG. 11A, followed by forming an insulating film P104 to fill the device isolation trench 104T and cover the main surface 102M of the substrate 102, and then, an ion implantation process may be performed to form a plurality of source/drain regions SD in the substrate 102. A portion, which fills the device isolation trench 104T, of the insulating film P104 may be a device isolation film 104. A portion, which covers the main surface 102M of the substrate 102, of the insulating film P104 may protect the main surface 102M of the substrate 102 during the ion implantation process for forming the plurality of source/drain regions SD or during a subsequent etching process.

Referring to FIG. 11C, a mask pattern M2 may be formed on the resulting product of FIG. 11B, and a portion of the insulating film P104 and a portion of the substrate 102 may be etched by using the mask pattern M2 as an etch mask, thereby forming a plurality of word line trenches WT, which extend lengthwise in the first horizontal direction (the X direction) across the plurality of source/drain regions SD and the device isolation film 104. Each of the plurality of word line trenches WT may include a first trench portion T1A having a lower surface, which exposes the substrate 102, and a second trench portion T1B having a lower surface, which exposes the device isolation film 104. The mask pattern M2 may include an oxide film, an amorphous carbon layer (ACL), a SiON film, or a combination thereof.

To form the plurality of word line trenches WT, a first etching process for etching the substrate 102 and the device isolation film 104 under the condition that the respective etch rates of the substrate 102 and the device isolation film 104 are approximately equal to each other, and a second etching process for etching the substrate 102 and the device isolation film 104 under the condition that the etch rate of the device isolation film 104 is greater than the etch rate of the substrate 102 may be sequentially performed in the stated order. As a result, a vertical level of the lower surface of the second trench portion T1B, which exposes the device isolation film 104, may be lower than a vertical level of the lower surface of the first trench portion T1A, which exposes the substrate 102. The first trench portion T1A of the second trench portion T1B of the word line trench WT may respectively have substantially equal or approximately similar widths in the second horizontal direction (the Y direction).

Referring to FIG. 11D, a silicon oxide dielectric film 120 may be formed on the resulting product of FIG. 11C. The silicon oxide dielectric film 120 may be formed to conformally cover each of the plurality of word line trenches WT. To form the silicon oxide dielectric film 120, a thermal oxidation or atomic layer deposition (ALD) process may be used.

Referring to FIG. 11E, a metal-containing layer 122L and an amorphous silicon layer 124 may be sequentially formed in the stated order on the resulting product of FIG. 11D to cover the silicon oxide dielectric film 120.

To form the metal-containing layer 122L and the amorphous silicon layer 124, an ALD process may be used. Respective processes of forming the metal-containing layer 122L and the amorphous silicon layer 124 may be consecutively performed in-situ in the same chamber without breaking the vacuum. The metal-containing layer 122L may be formed on the silicon oxide dielectric film 120 to fill only a portion of the word line trench WT. The amorphous silicon layer 124 may include a portion filling the word line trench WT remaining over the metal-containing layer 122L and a portion arranged outside the word line trench WT to cover the metal-containing layer 122L.

Referring to FIG. 11F, in the resulting product of FIG. 11E, a portion of each of the amorphous silicon layer 124 and the metal-containing layer 122L may be polished by a chemical mechanical polishing (CMP) process and then cleaned, thereby exposing a metal-containing word line 122, which covers the upper surface of the device isolation film 104. Next, by removing the respective remaining portions of the amorphous silicon layer 124 and the metal-containing layer 122L by etch-back, the metal-containing word line 122 may be formed to fill a lower portion of the word line trench WT, and only a portion of the amorphous silicon layer 124 may remain to fill the upper internal space 122S of the metal-containing word line 122.

Referring to FIG. 11G, a dopant D may be implanted into the resulting product of FIG. 11F, thereby forming a doped silicon layer 124D from the amorphous silicon layer 124. The dopant D may be selected from phosphorus (P), boron (B), arsenic (As), germanium (Ge), and a combination thereof.

An implantation process of the dopant D for forming the doped silicon layer 124D may be performed by a gas-phase doping process. In the case where a dopant having a relatively large particle size is selected as the dopant D, when the dopant D is implanted by a gas-phase doping process while the metal-containing word line 122, the silicon oxide dielectric film 120, and the amorphous silicon layer 124 are exposed, the dopant D may be selectively implanted only into the amorphous silicon layer 124 rather than implanted into the metal-containing word line 122 and the silicon oxide dielectric film 120. In some implementations, to form the doped silicon layer 124D, a gas source including phosphine (PH₃) may be supplied onto the substrate 102, but the present disclosure is not limited thereto.

Referring to FIG. 11H, by performing heat treatment HT on the resulting product of FIG. 11G, a portion of the metal-containing word line 122 may be oxidized from an interface between the silicon oxide dielectric film 120 and the metal-containing word line 122, thereby forming a metal oxide dielectric film 123 between the silicon oxide dielectric film 120 and the metal-containing word line 122. Here, impurities in the doped silicon layer 124D may diffuse into a portion, which faces the doped silicon layer 124D, of the metal oxide dielectric film 123, thereby obtaining the metal oxide dielectric film 123 including a first local region 123A and a second local region 123B, which respectively have different dopant contents.

The heat treatment HT may be performed by a rapid thermal anneal (RTA) process. For example, the heat treatment HT may be performed at a temperature selected from a range of about 800° C. to about 1050° C. for about 0.1 seconds to about 2 minutes, but the present disclosure is not limited thereto.

An interface dipole layer DPL may be formed along an interface between the second local region 123B of the metal oxide dielectric film 123 and the silicon oxide dielectric film 120. The interface dipole layer DPL may include a plurality of dipoles DP arranged along the interface between the second local region 123B of the metal oxide dielectric film 123 and the silicon oxide dielectric film 120.

Referring to FIG. 11I, by depositing an insulating film on the resulting product of FIG. 11H, polishing the insulating film by CMP, and then performing cleaning, an insulating capping pattern 128 may be formed to fill an upper space of the word line trench WT, and unnecessary films remaining on or over the substrate 102 may be removed, thereby exposing the upper surface of each of the active region AC of the substrate 102 and the device isolation film 104.

Next, as shown in FIGS. 2 and 3, a buffer insulating film 130, a plurality of direct contacts DC, a plurality of bit lines BL, a plurality of insulating spacers 146, an insulating fence 142, a plurality of conductive plugs 140P, a metal silicide film 172, a conductive landing pad LP, and an insulating film 180 may be formed on or over the substrate 102, thereby fabricating the integrated circuit device 100 having the configuration shown in FIGS. 1 to 5.

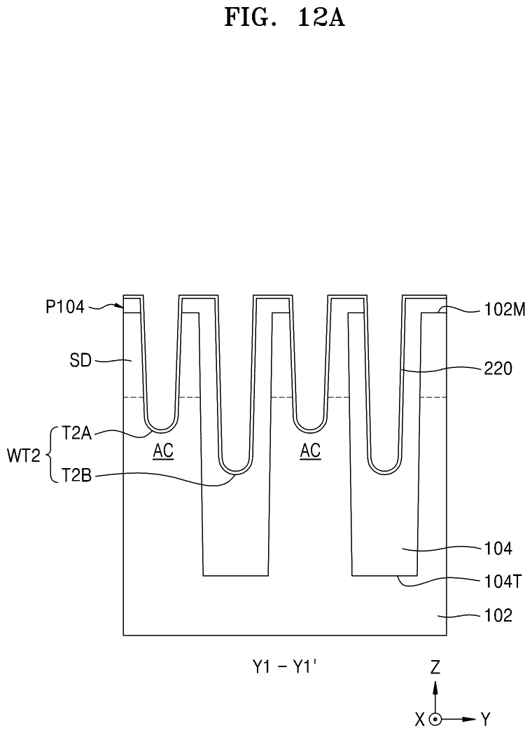

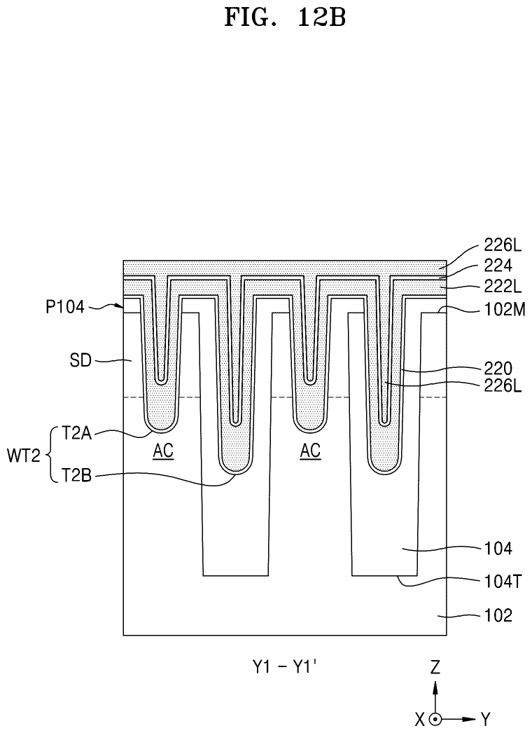

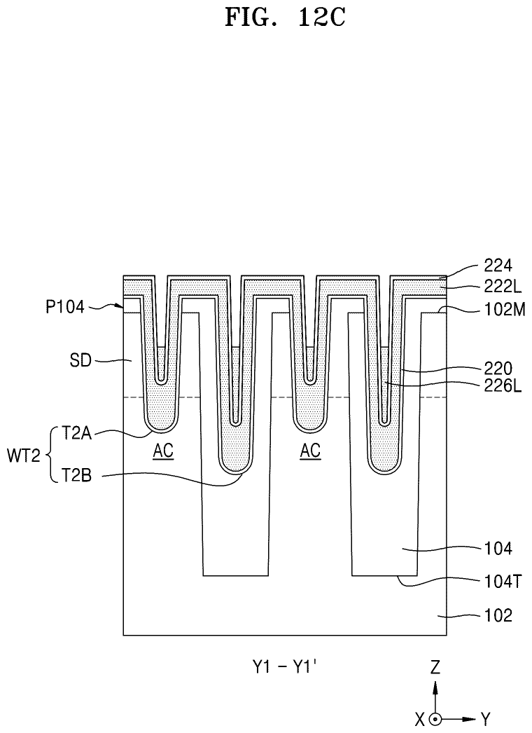

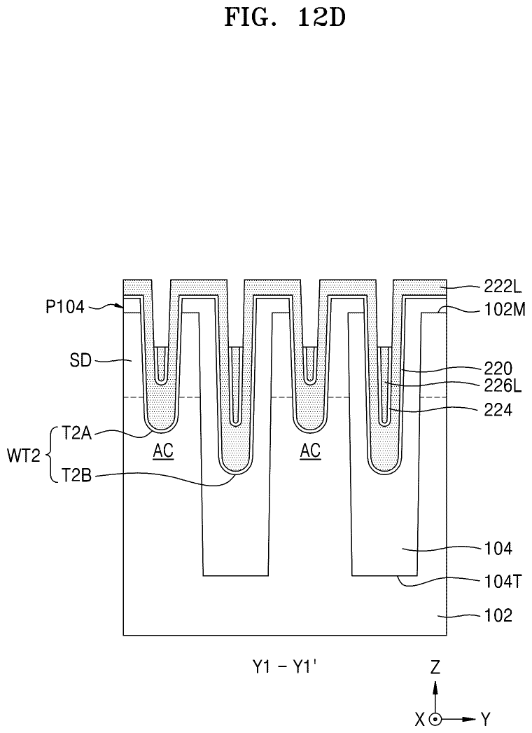

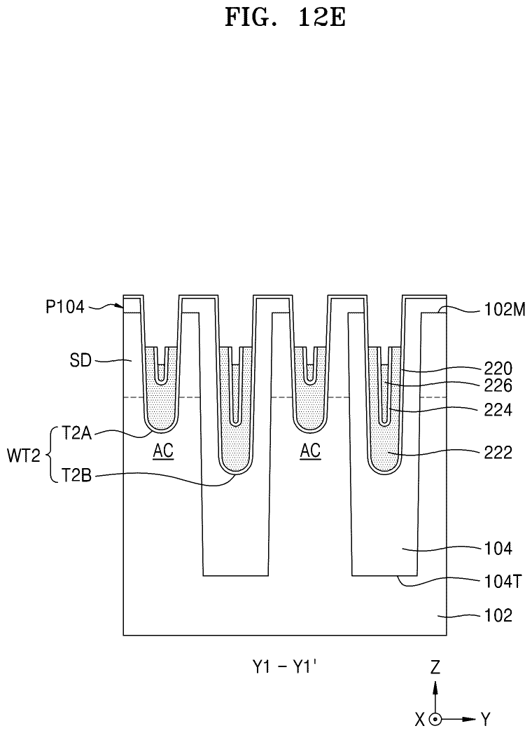

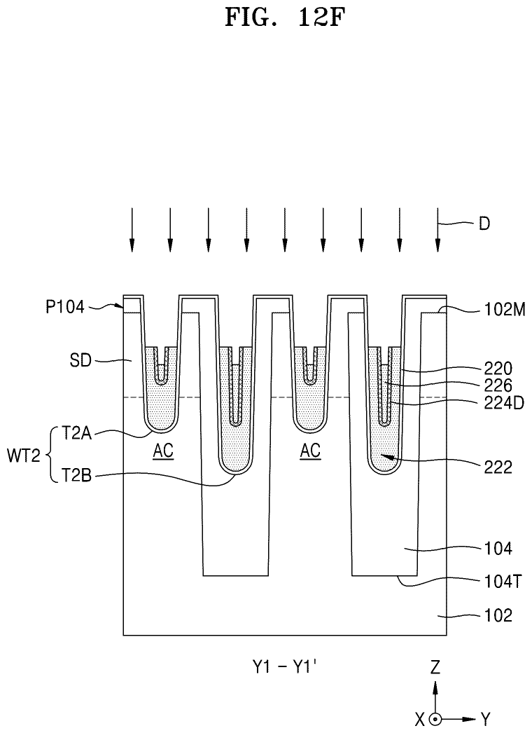

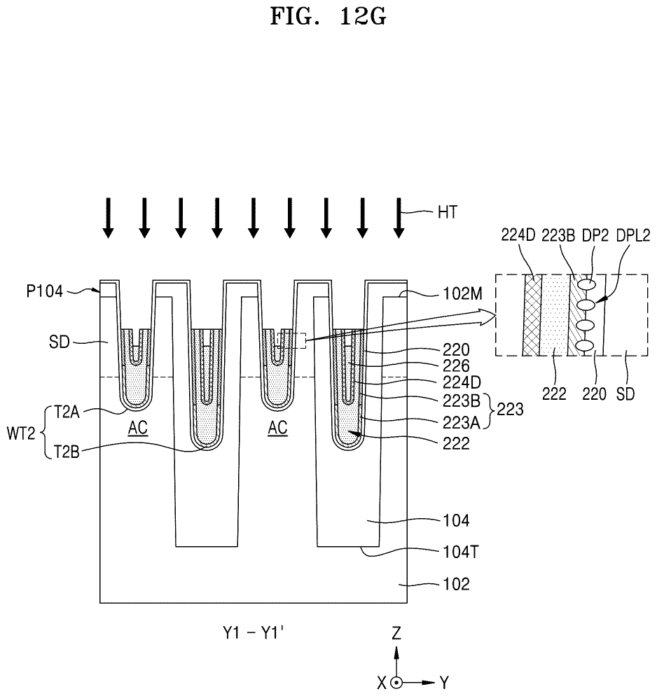

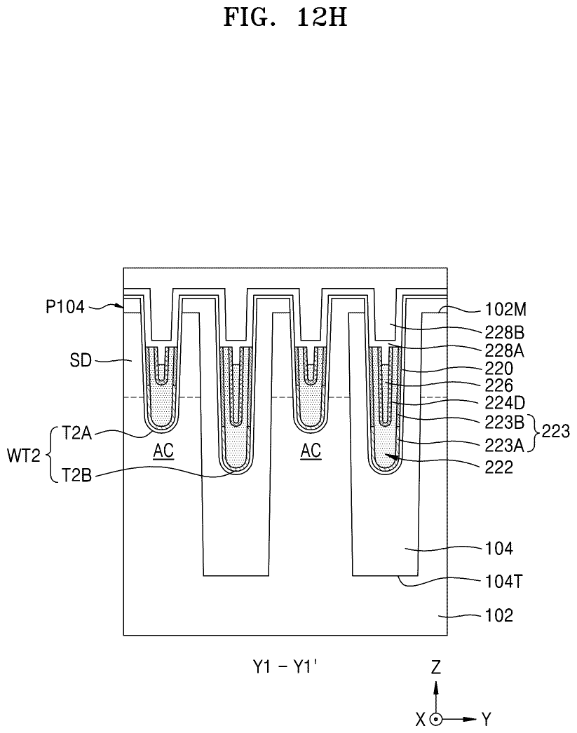

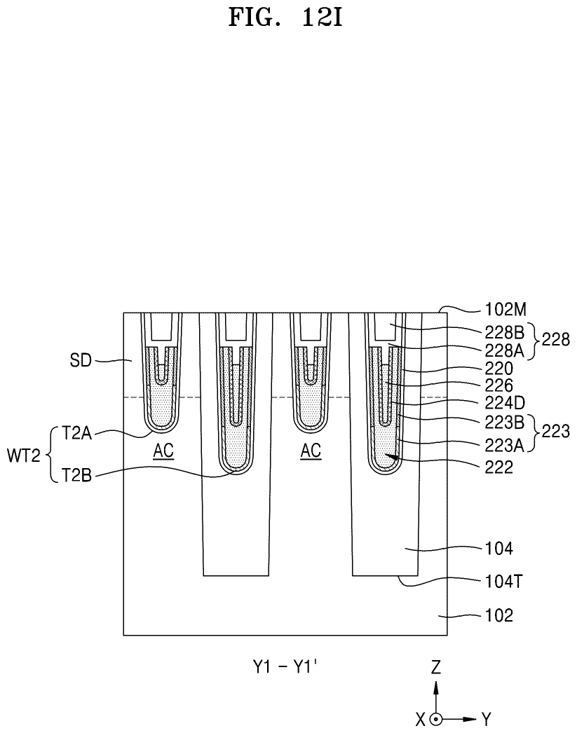

FIGS. 12A to 12I are cross-sectional views respectively illustrating a sequence of processes of a method of fabricating an integrated circuit device, according to some implementations. FIGS. 12A to 12I each illustrate a cross-sectional configuration of a region corresponding to a cross-section taken along the line Y1-Y1′ of FIG. 1 according to the sequence of processes. An example of a method of fabricating the integrated circuit device 200 shown in FIGS. 6 and 7 is described with reference to FIGS. 12A to 12I. In FIGS. 12A to 12I, the same reference numerals as in FIGS. 1 to 7 respectively denote the same members, and here, repeated descriptions thereof are omitted.

Referring to FIG. 12A, similar processes to those described with reference to FIGS. 11A to 11D may be performed, thereby forming a plurality of word line trenches WT2 in the substrate 102 and forming a silicon oxide dielectric film 220 on or over the substrate 102.

Referring to FIG. 12B, a first metal-containing layer 222L, an amorphous silicon liner 224, and a second metal-containing layer 226L may be formed in the stated order in each of the plurality of word line trenches WT2 to sequentially cover the silicon oxide dielectric film 220 in the stated order. To form the first metal-containing layer 222L, the amorphous silicon liner 224, and the second metal-containing layer 226L, an ALD process may be used. Respective processes of forming the first metal-containing layer 222L, the amorphous silicon liner 224, and the second metal-containing layer 226L may be consecutively performed in-situ in the same chamber without breaking the vacuum.

Each of the first metal-containing layer 222L and the second metal-containing layer 226L may include a metal-containing film. The metal-containing film may include a conductive metal nitride film. For example, each of the first metal-containing layer 222L and the second metal-containing layer 226L may include, but is not limited to, a TiN film. In some implementations, the first metal-containing layer 222L may be formed with a thickness of 30 Å or less, for example, about 4 Å to about 20 Å, in the word line trench WT2, but the present disclosure is not limited thereto. The amorphous silicon liner 224 may be formed to cover the upper surface of the first metal-containing layer 222L with a constant thickness. The second metal-containing layer 226L may be formed on the amorphous silicon liner 224 to fill the remaining space of the word line trench WT2.

Referring to FIG. 12C, in the resulting product of FIG. 12B, the second metal-containing layer 226L that is exposed may be selectively wet-etched, thereby causing the second metal-containing layer 226L to remain only in each of the plurality of word line trenches WT2. As a result, in each of the plurality of word line trenches WT2, the amorphous silicon liner 224 may be exposed.

Referring to FIG. 12D, in the resulting product of FIG. 12C, the amorphous silicon liner 224 that is exposed may be selectively wet-etched, thereby exposing the first metal-containing layer 222L in each of the plurality of word line trenches WT2. A portion of the amorphous silicon liner 224 may intactly remain, the portion being arranged between the first metal-containing layer 222L and the second metal-containing layer 226L.

Referring to FIG. 12E, in the resulting product of FIG. 12D, the first metal-containing layer 222L that is exposed may be selectively wet-etched. As a result, a metal-containing word line 222, which includes the remaining portion of the first metal-containing layer 222L, may be formed in each of the plurality of word line trenches WT2.

While the first metal-containing layer 222L is being selectively wet-etched for forming the metal-containing word line 222, a portion of the second metal-containing layer 226L including the same material as the first metal-containing layer 222L may also be wet-etched together. As a result, an additional electrode layer 226, which includes the remaining portion of the second metal-containing layer 226L, may be formed in each of the plurality of word line trenches WT2.

Referring to FIG. 12F, in a similar manner to that described with reference to FIG. 11G, a doped silicon layer 224D may be formed from the amorphous silicon liner 224 by implanting a dopant D into the resulting product of FIG. 12E. The dopant D may be selected from phosphorus (P), boron (B), arsenic (As), germanium (Ge), and a combination thereof.

Referring to FIG. 12G, in a similar manner to that described with reference to FIG. 11H, by performing heat treatment HT on the resulting product of FIG. 12F, a portion of the metal-containing word line 222 may be oxidized from an interface between the silicon oxide dielectric film 220 and the metal-containing word line 222 in the resulting product of FIG. 12F, thereby forming a metal oxide dielectric film 223 between the silicon oxide dielectric film 220 and the metal-containing word line 222. Here, impurities in the doped silicon layer 224D may diffuse into a portion, which faces the doped silicon layer 224D, of the metal oxide dielectric film 223, thereby obtaining the metal oxide dielectric film 223 including a first local region 223A and a second local region 223B, which respectively have different dopant contents.

An interface dipole layer DPL2 may be formed along an interface between the second local region 223B of the metal oxide dielectric film 223 and the silicon oxide dielectric film 220. The interface dipole layer DPL2 may include a plurality of dipoles DP2 arranged along the interface between the second local region 223B of the metal oxide dielectric film 223 and the silicon oxide dielectric film 220.

Referring to FIG. 12H, an insulating capping liner 228A and an insulating capping plug 228B may be sequentially formed in the stated order on the resulting product of FIG. 12G.

Referring to FIG. 12I, in the resulting product of FIG. 12H, a portion of each of the insulating capping liner 228A and the insulating capping plug 228B may be polished by CMP, followed by performing cleaning, thereby forming an insulating capping pattern 228 to fill an upper space of the word line trench WT2 and exposing the upper surface of each of the active region AC of the substrate 102 and the device isolation film 104. The insulating capping pattern 228 may include the respective remaining portions of the insulating capping liner 228A and the insulating capping plug 228B.

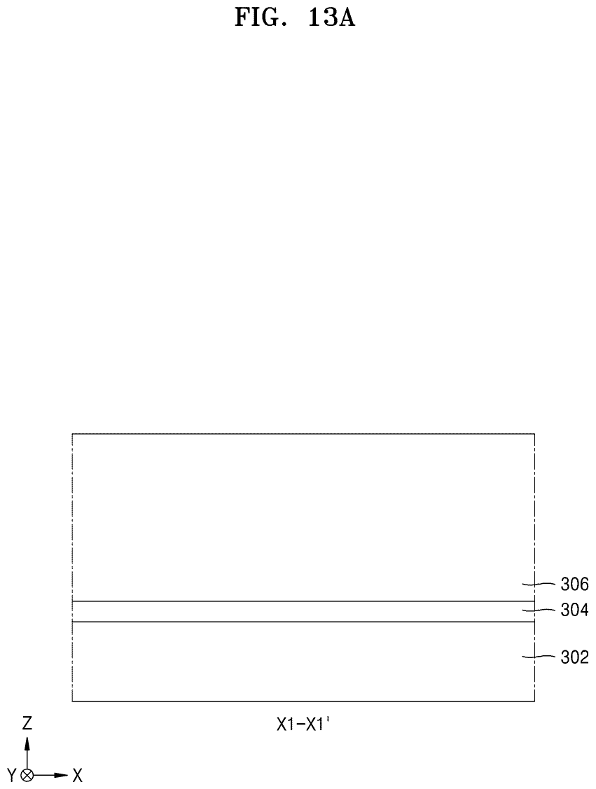

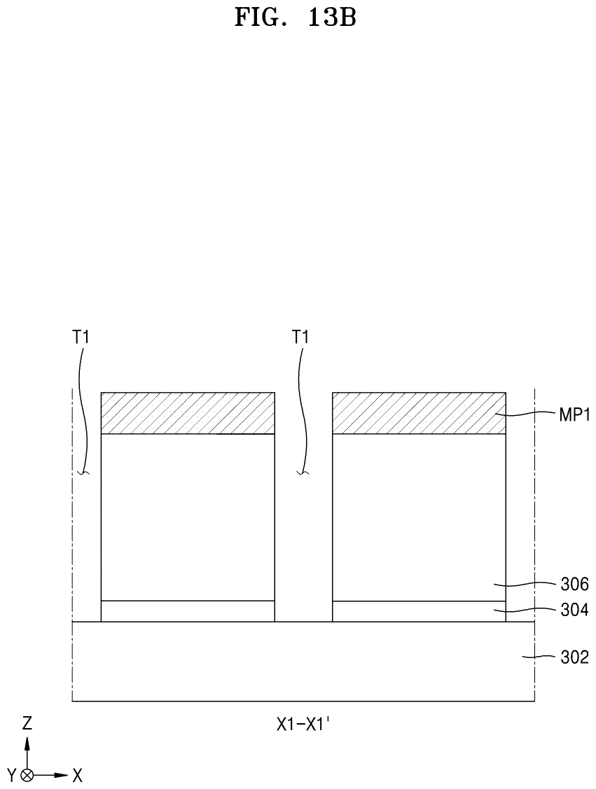

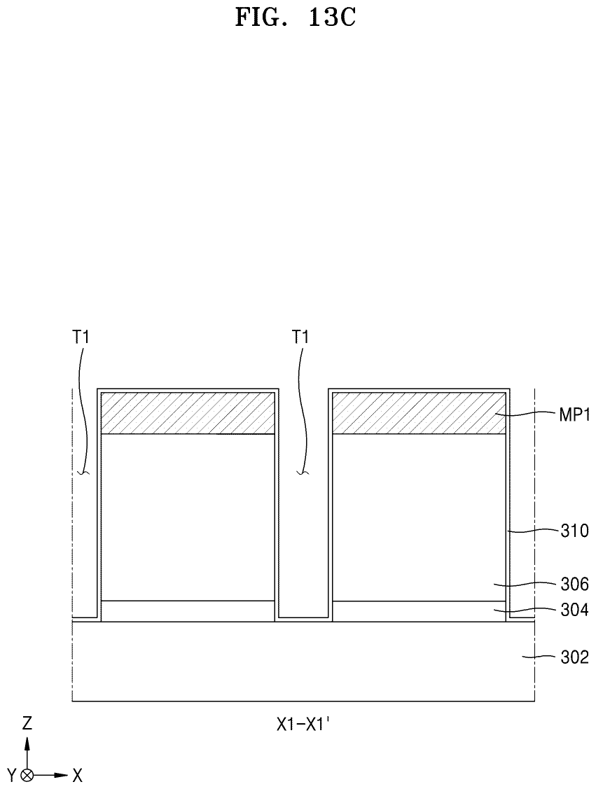

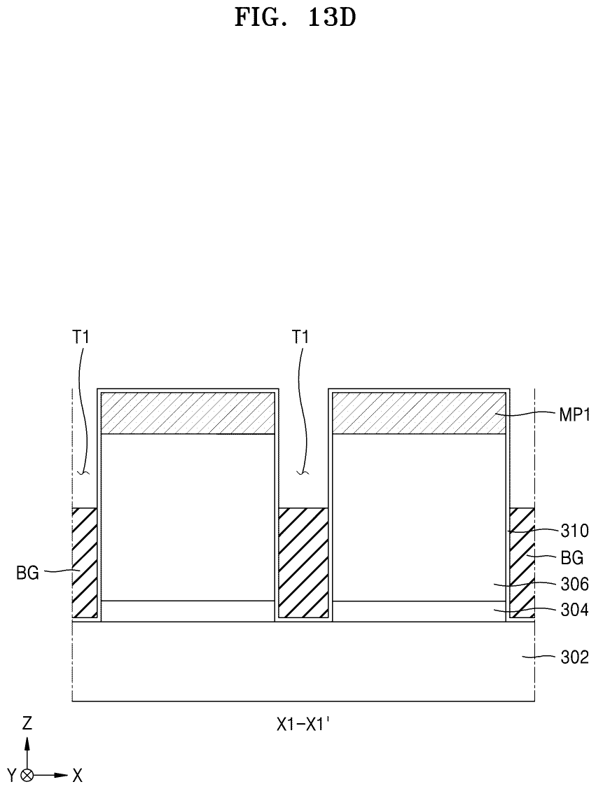

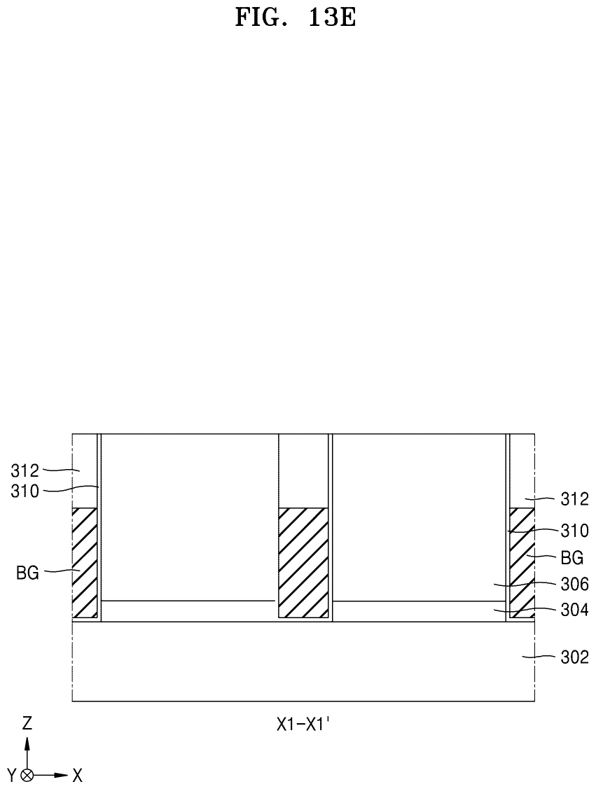

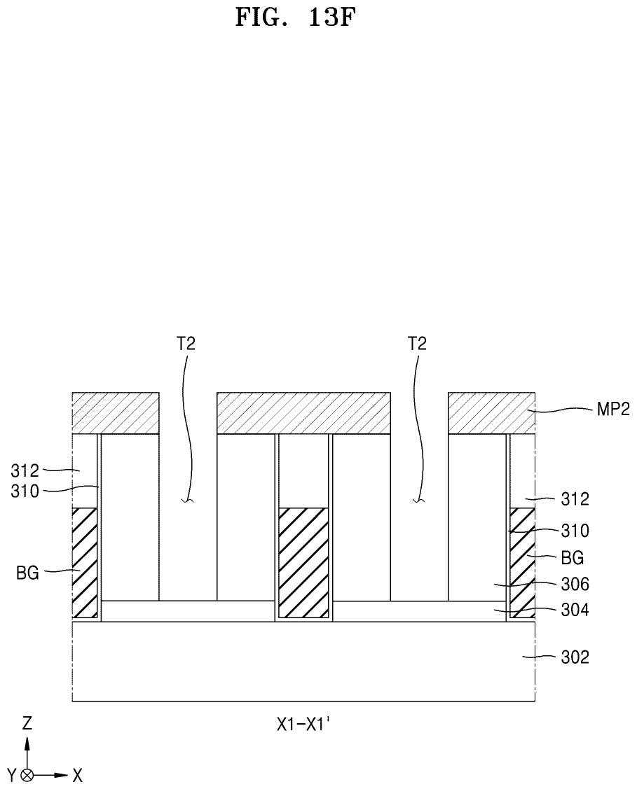

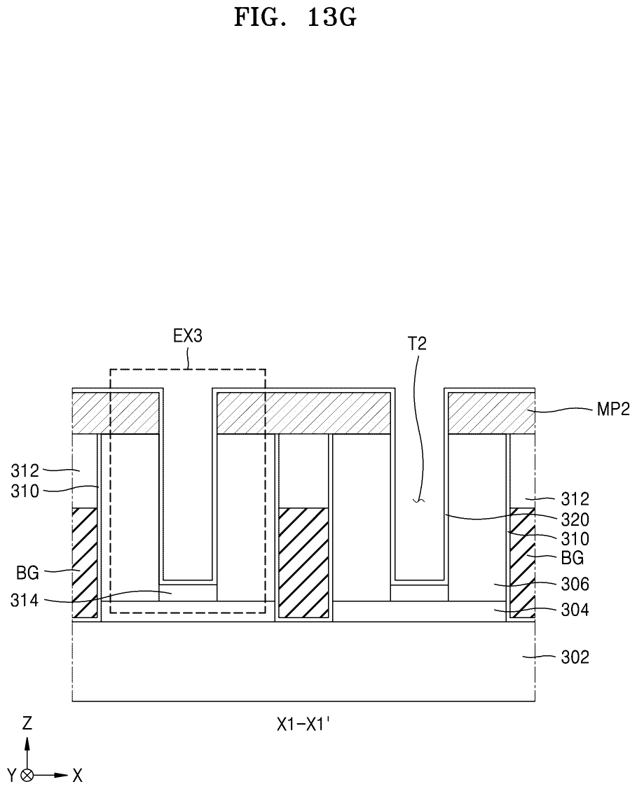

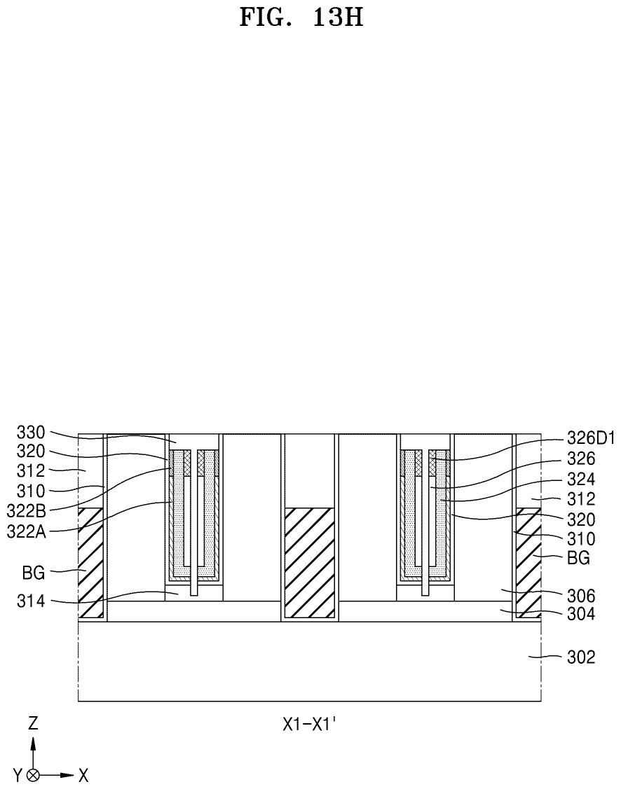

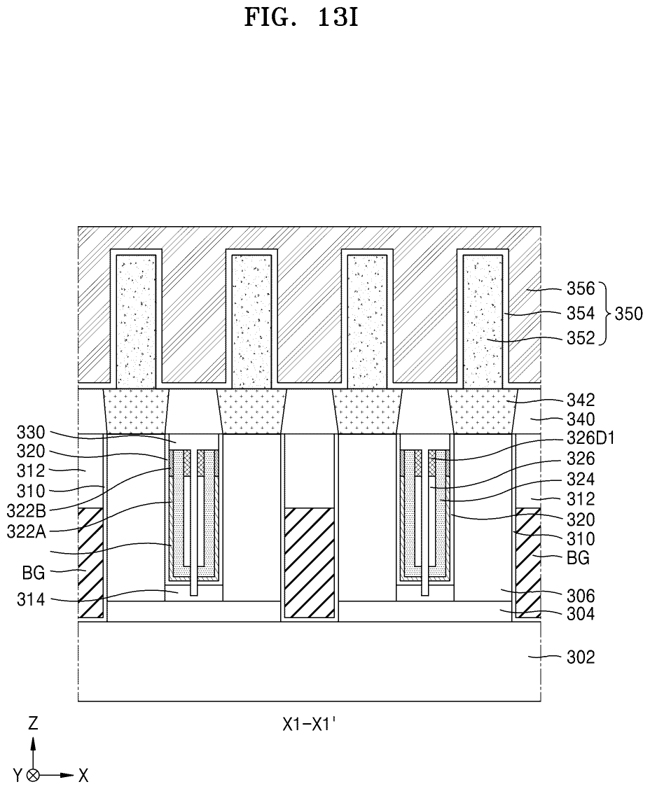

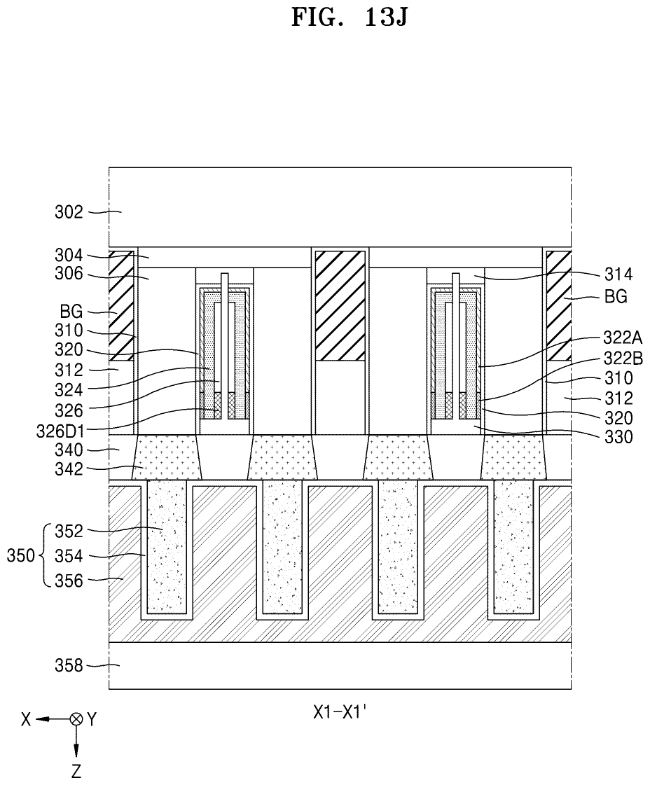

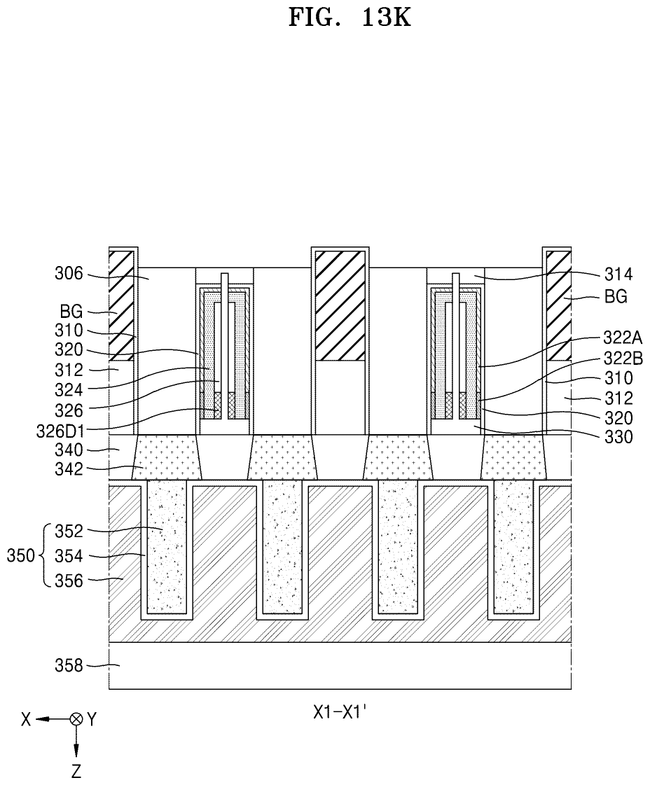

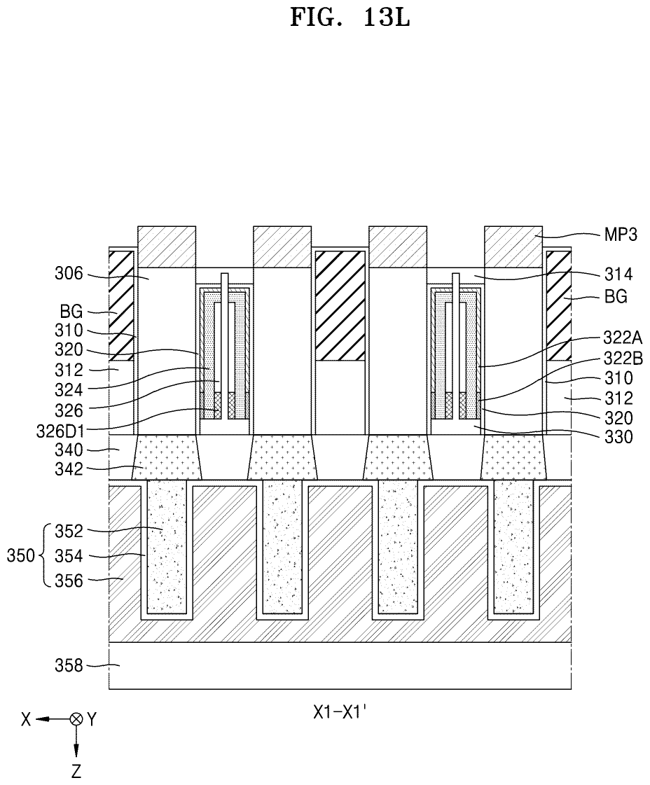

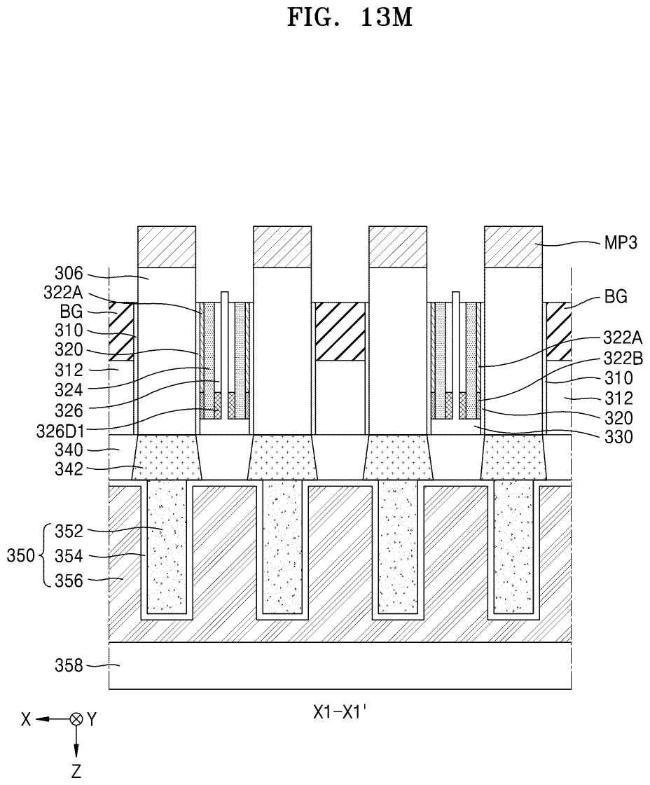

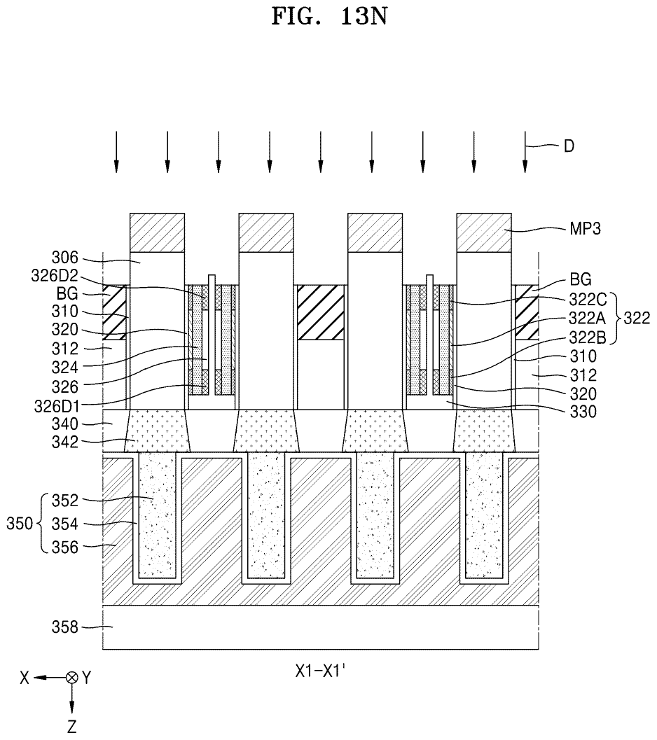

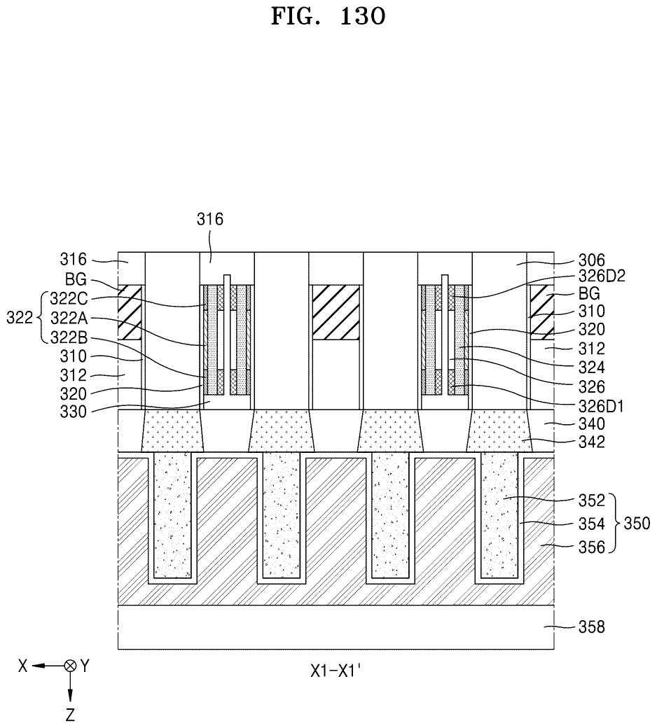

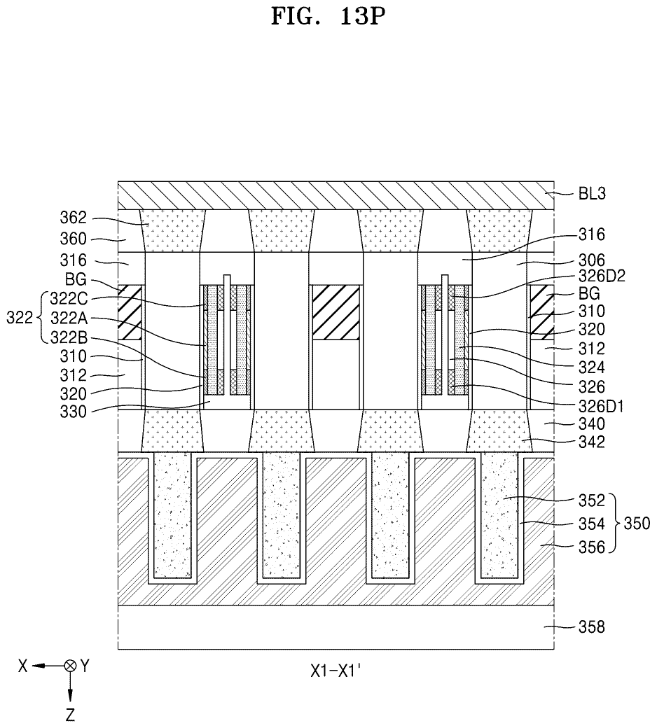

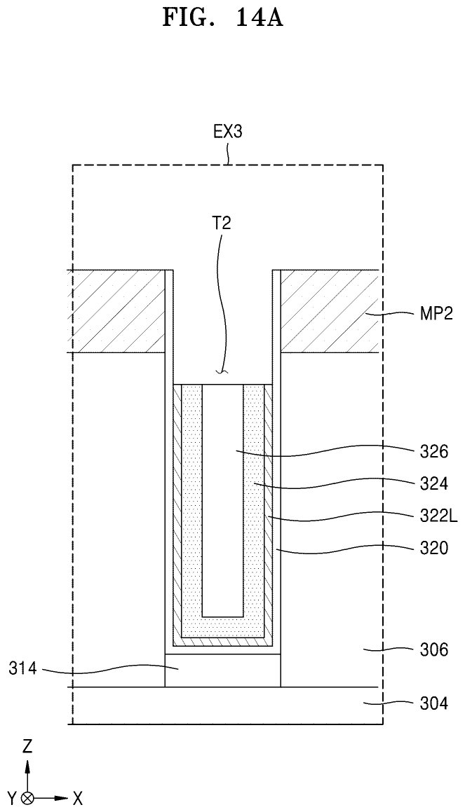

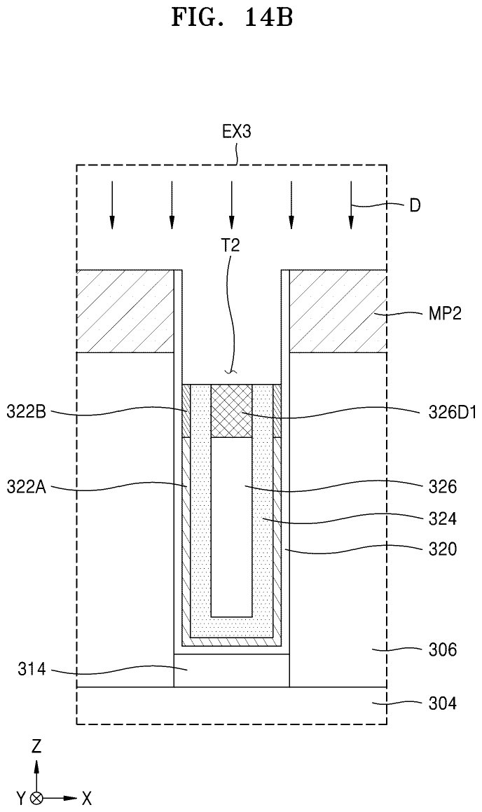

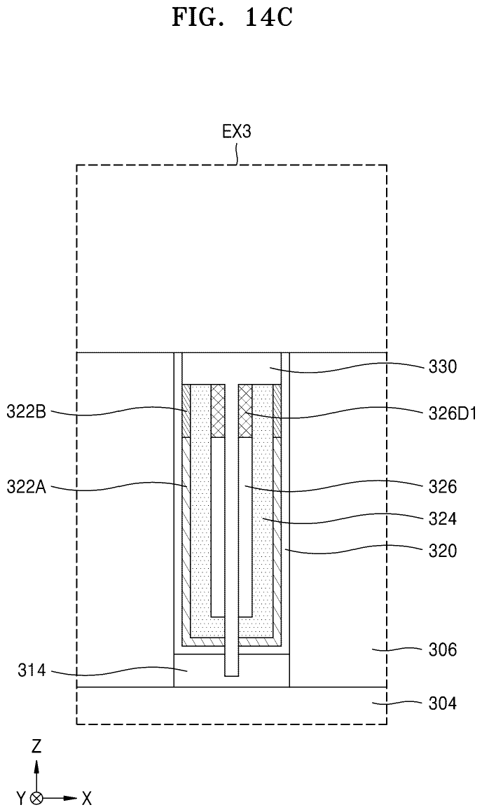

FIGS. 13A to 13P and 14A to 14C are cross-sectional views illustrating a method of fabricating an integrated circuit device, according to some implementations. More specifically, FIGS. 13A to 13P are cross-sectional views of a region corresponding to the cross-section taken along the line X1-X1′ of FIG. 8 according to a sequence of processes, and FIGS. 14A to 14C are enlarged cross-sectional views each illustrating components in a region corresponding to a region EX3 of FIG. 13G according to the sequence of processes, for a more detailed description of the process described with reference to FIG. 13H. An example of a method of fabricating the integrated circuit device 300 shown in FIGS. 8 and 9 is described with reference to FIGS. 13A to 13P and 14A to 14C. In FIGS. 13A to 13P and 14A to 14C, the same reference numerals as in FIGS. 8 and 9 respectively denote the same members, and here, repeated descriptions thereof are omitted.

Referring to FIG. 13A, a substrate structure including a substrate 302, a buried insulating layer 304, and an active region 306 may be prepared.

The substrate structure may include a silicon-on-insulator (SOI) substrate. The substrate 302 may include a silicon substrate. The buried insulating layer 304 may include a silicon oxide film. The active region 306 may include at least one selected from Si, Ge, SiGe, SiC, GaAs, InAs, and InP. In some implementations, the active region 306 may include an impurity-doped well or an impurity-doped structure.

Referring to FIG. 13B, a mask pattern MP1 may be formed on the active region 306 of the substrate structure. The mask pattern MP1 may include a silicon nitride film. In some implementations, an oxide film may be arranged between the active region 306 and the mask pattern MP1.

Some portions of the substrate structure may be etched by using the mask pattern MP1 as an etch mask, thereby forming a plurality of first trenches T1. The plurality of first trenches T1 may be formed to pass through the active region 306 and the buried insulating layer 304 in the vertical direction (the Z direction) and to extend lengthwise in the second horizontal direction (the Y direction). The active region 306 may be divided into a plurality of active regions 306 by the plurality of first trenches T1.

Referring to FIG. 13C, in the resulting product of FIG. 13B, a back gate dielectric film 310 may be formed to conformally cover inner surfaces of each of the plurality of first trenches T1.

Referring to FIG. 13D, a conductive material may be deposited on the resulting product of FIG. 13C and then etched back, thereby forming a back gate electrode BG on the back gate dielectric film 310 to fill a portion of each of the plurality of first trenches T1.

Referring to FIG. 13E, in the resulting product of FIG. 13D, an insulating film may be formed to fill the first trench T1 remaining over the back gate electrode BG, followed by removing the mask pattern MP1, thereby exposing the upper surface of the active region 306. In the first trench T1, a first capping insulating pattern 312, which includes a remaining portion of the insulating film, may remain on the back gate electrode BG. The upper surface of the first capping insulating pattern 312 may be coplanar with the upper surface of the active region 306.

Referring to FIG. 13F, a mask pattern MP2 may be formed on the resulting product of FIG. 13E, followed by etching respective portions of the plurality of active regions 306 by using the mask pattern MP2 as an etch mask, thereby forming a plurality of second trenches T2 to expose the buried insulating layer 304. The mask pattern MP2 may include a silicon nitride film. In some implementations, an oxide film may be arranged between the plurality of active regions 306 and the mask pattern MP2.

Referring to FIG. 13G, in the resulting product of FIG. 13F, a front gate spacer 314 may be formed to fill a portion of each of the plurality of second trenches T2, and a silicon oxide dielectric film 320 may be formed to conformally cover the upper surface of the front gate spacer 314 and sidewalls of the active region 306, which are exposed in the second trench T2.

Referring to FIG. 13H, in the resulting product of FIG. 13G, a structure including a pair of metal oxide dielectric films 322, a pair of metal-containing word lines 324, a pair of silicon layers 326, a pair of doped silicon layers 326D1 and 326D2, and an isolation insulating pattern 330 may be formed in each of the plurality of second trenches T2.

The process of FIG. 13H is described in more detail with reference to FIGS. 14A to 14C.

Referring first to FIG. 14A, in the resulting product of FIG. 13G, a structure, in which a metal oxide film 322L, a metal-containing word line 324, and a silicon layer 326 are sequentially stacked in the stated order, may be formed in each of the plurality of second trenches T2. While the structure is being formed, portions, which cover the mask pattern MP2, of the silicon oxide dielectric film 320 may be partially removed. In some implementations, the metal oxide film 322L may include a titanium oxide film, the metal-containing word line 324 may include a TiN film, and the silicon layer 326 may include amorphous silicon.

In some implementations, to form the structure, in which the metal oxide film 322L, the metal-containing word line 324, and the silicon layer 326 are sequentially stacked in the stated order, in each of the plurality of second trenches T2, a titanium oxide film, a TiN film, and an amorphous silicon layer may be sequentially stacked in the stated order on the resulting product of FIG. 13G, and then, may be etched back such that the titanium oxide film, the TiN film, and the amorphous silicon layer remain only in a lower portion of each of the plurality of second trenches T2. In some implementations, to form the structure, in which the metal oxide film 322L, the metal-containing word line 324, and the silicon layer 326 are sequentially stacked in the stated order, in each of the plurality of second trenches T2, a TiN film may be formed first on the resulting product of FIG. 13G, and then, the metal oxide film 322L including a titanium oxide film may be formed by oxidizing a portion of the TiN film from an interface between the silicon oxide dielectric film 320 and the TiN film. Next, an amorphous silicon layer may be formed on the TiN film, and then, a portion of the obtained resulting product may be removed by etch-back.

Referring to FIG. 14B, in a similar manner to that described with reference to FIG. 11G, a dopant D may be implanted into the resulting product of FIG. 14A, thereby changing a portion of the silicon layer 326 into a doped silicon layer 326D1. The dopant D may be selected from phosphorus (P), boron (B), arsenic (As), germanium (Ge), and a combination thereof.

Next, impurities may be diffused from the doped silicon layer 326D1 into a portion of the metal oxide film 322L, thereby forming, from the metal oxide film 322L, a first local region 322A and an upper second local region 322B respectively having different dopant concentrations. A dopant content ratio in the upper second local region 322B may be greater than a dopant content ratio in the first local region 322A. The first local region 322A may include no dopant or may include a dopant in an amount equal to or less than a detection limit even though including the dopant.

Referring to FIG. 14C, in the resulting product of FIG. 14B, the doped silicon layer 326D1, the silicon layer 326, the metal-containing word line 324, the first local region 322A, and the silicon oxide dielectric film 320, in the second trench T2, may be etched, thereby forming a separation space, which divides each thereof into two portions. Here, a portion of the front gate spacer 314 may also be etched due to over-etch. Next, an isolation insulating pattern 330 may be formed in the second trench T2 to fill the separation space. As a result, a resulting product shown in FIG. 13H may be obtained.

Referring to FIG. 13I, an interlayer dielectric 340, and a plurality of contact plugs 342, which each pass through the interlayer dielectric 340 in the vertical direction (the Z direction) to be connected to an active region 306, may be formed on the resulting product of FIG. 13G. Next, a capacitor structure 350 may be formed on the obtained resulting product, the capacitor structure 350 including a plurality of lower electrodes 352 respectively connected to the plurality of contact plugs 342, a capacitor dielectric film 354 conformally covering the respective surfaces of the plurality of lower electrodes 352, and an upper electrode 356 covering the plurality of lower electrodes 352 with the capacitor dielectric film 354 therebetween.

Referring to FIG. 13J, in the resulting product of FIG. 13I, an insulating film 358 may be formed to cover the capacitor structure 350, followed by turning over the obtained resulting product to invert upper and lower portions thereof in the vertical direction (the Z direction), thereby causing the substrate 302 to face upwards in the vertical direction (the Z direction).

Referring to FIG. 13K, the substrate 302 may be removed from the resulting product of FIG. 13J such that the buried insulating layer 304 and the plurality of back gate dielectric films 310 are exposed. To remove the substrate 302, a grinding process and a wet-etching process may be sequentially performed in the stated order on the substrate 302. Next, the buried insulating layer 304 that is exposed may be removed, thereby exposing the plurality of active regions 306 and the plurality of front gate spacers 314.

Referring to FIG. 13L, a mask pattern MP3 may be formed on the resulting product of FIG. 13K to cover the plurality of active regions 306. The mask pattern MP3 may include a silicon nitride film. In some implementations, an oxide film may be arranged between the active region 306 and the mask pattern MP3.

Referring to FIG. 13M, in the resulting product of FIG. 13L, the front gate spacer 314 may be selectively removed by using the mask pattern MP3 as an etch mask to expose the plurality of silicon oxide dielectric films 320, followed by removing exposed portions of the plurality of silicon oxide dielectric films 320, and then, a portion of each of the first local region 322A and the metal-containing word line 324 may be removed, thereby exposing the silicon layer 326. Here, each of the plurality of back gate dielectric films 310 and the plurality of back gate electrodes BG may also be partially removed, and thus, the thickness thereof in the vertical direction (the Z direction) may also be reduced.

Referring to FIG. 13N, in a similar manner to that described with reference to FIG. 14B, a dopant D may be implanted into the resulting product of FIG. 13M, thereby changing another portion of the silicon layer 326 into a doped silicon layer 326D2. The dopant D may be selected from phosphorus (P), boron (B), arsenic (As), germanium (Ge), and a combination thereof.

Next, impurities may be diffused from the doped silicon layer 326D2 into a portion of the first local region 322A, thereby changing the portion of the first local region 322A into a lower second local region 322C. A dopant content ratio in the lower second local region 322C may be greater than the dopant content ratio in the first local region 322A. The dopant content ratio in the lower second local region 322C may be equal to or different from the dopant content ratio in the upper second local region 322B.

Referring to FIG. 13O, in the resulting product of FIG. 13M, a plurality of second capping insulating patterns 316 may each be formed to cover a structure including the doped silicon layer 326D2 and the lower second local region 322C, the back gate electrode BG, and the back gate dielectric film 310. After the plurality of second capping insulating patterns 316 are formed, the respective exposed surfaces of the plurality of second capping insulating patterns 316 may be coplanar with the respective exposed surfaces of the plurality of active regions 306.

Referring to FIG. 13P, an interlayer dielectric 360, and a plurality of contact plugs 362, which pass through the interlayer dielectric 360 in the vertical direction (the Z direction), may be formed on the resulting product of FIG. 13O, followed by forming a conductive line BL3 on the interlayer dielectric 360 and the plurality of contact plugs 362, thereby fabricating the integrated circuit device 300 shown in FIGS. 8 and 9.

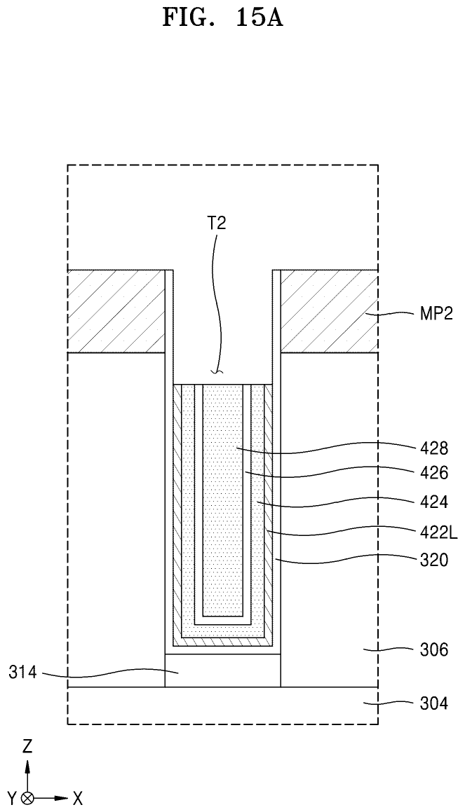

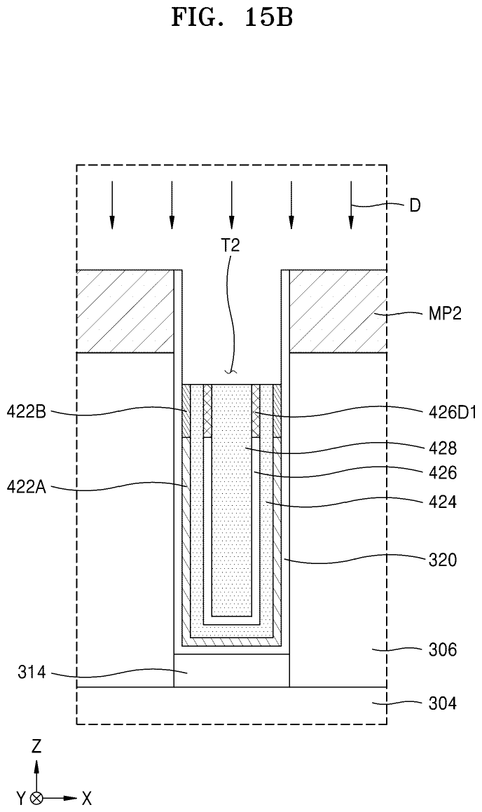

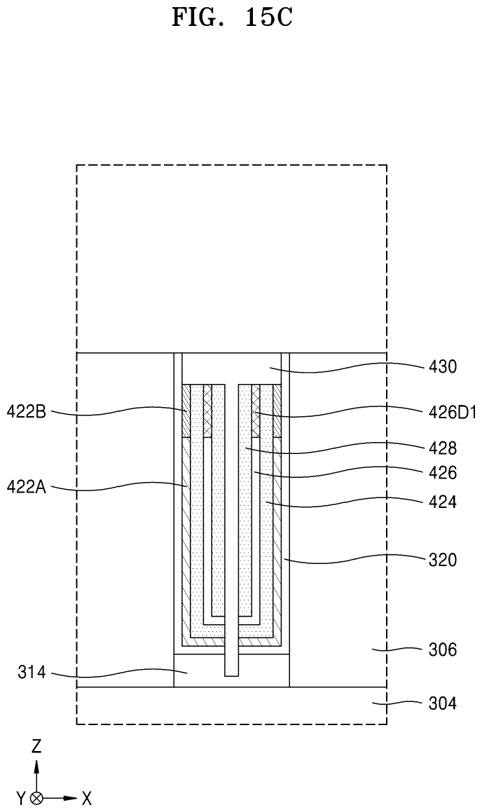

FIGS. 15A to 15C are cross-sectional views illustrating a method of fabricating an integrated circuit device, according to some implementations. FIGS. 15A to 15C each illustrate an enlarged view of components in a region corresponding to the region EX3 of FIG. 13G according to a sequence of processes. An example of a method of fabricating the integrated circuit device 400 shown in FIG. 10 is described with reference to FIGS. 15A to 15C. In FIGS. 15A to 15C, the same reference numerals as in FIGS. 8 to 14C respectively denote the same members, and here, repeated descriptions thereof are omitted.

Referring to FIG. 15A, the processes described with reference to FIGS. 13A to 13G may be performed, and then, a structure, in which a metal oxide film 422L, a metal-containing word line 424, a silicon layer 426, and an additional electrode layer 428 are sequentially stacked in the stated order, may be formed in each of the plurality of second trenches T2 in the resulting product of FIG. 13G. In some implementations, the metal oxide film 422L may include a titanium oxide film, each of the metal-containing word line 424 and the additional electrode layer 428 may include a TiN film, and the silicon layer 426 may include amorphous silicon.

Referring to FIG. 15B, in a similar manner to that described with reference to FIG. 14B, a dopant D may be implanted into the resulting product FIG. 15A, thereby changing a portion of the silicon layer 426 into a doped silicon layer 426D1. The dopant D may be selected from phosphorus (P), boron (B), arsenic (As), germanium (Ge), and a combination thereof.

Next, impurities may be diffused from the doped silicon layer 426D1 into a portion of the metal oxide film 422L, thereby forming, from the metal oxide film 422L, a first local region 422A and an upper second local region 422B respectively having different dopant concentrations. A dopant content ratio in the upper second local region 422B may be greater than a dopant content ratio in the first local region 422A. The first local region 422A may include no dopant or may include a dopant in an amount equal to or less than a detection limit even though including the dopant.

Referring to FIG. 15C, the additional electrode layer 428, the silicon layer 426, the metal-containing word line 424, the first local region 422A, and the silicon oxide dielectric film 320, in the second trench T2 of the resulting product of FIG. 15B, may be etched, thereby forming a separation space, which divides each thereof into two portions. Here, a portion of the front gate spacer 314 may also be etched due to over-etch. Next, an isolation insulating pattern 430 may be formed in the second trench T2 to fill the separation space.

Next, similar processes to those described with reference to FIGS. 13I to 13P may be performed, thereby fabricating the integrated circuit device 400.

Heretofore, although the examples of the methods of fabricating the integrated circuit devices 100, 200, 300, and 400 shown in FIGS. 1 to 10 have been described with reference to FIGS. 11A to 15C, the present disclosure is not limited thereto. It will be understood by those of ordinary skill in the art that, by making various modifications and changes to the examples set forth above without departing from the spirit and scope of the present disclosure, the integrated circuit devices 100, 200, 300, and 400 shown in FIGS. 1 to 10 and integrated circuit devices variously modified and changed therefrom may be fabricated.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. An integrated circuit device comprising:
an active region;
a silicon oxide dielectric film covering the active region;
a metal oxide dielectric film being apart from the active region, the silicon oxide dielectric film being between the metal oxide dielectric film and the active region, the metal oxide dielectric film comprising a first local region and a second local region, the second local region having a dopant content ratio greater than a dopant content ratio of the first local region;
a metal-containing word line being apart from the silicon oxide dielectric film, each of the first local region and the second local region of the metal oxide dielectric film being between the metal-containing word line and the silicon oxide dielectric film; and
a doped silicon layer comprising a portion that is in contact with the metal-containing word line and faces the second local region of the metal oxide dielectric film.

2. The integrated circuit device of claim 1, wherein the metal-containing word line comprises:
a lower electrode portion contacting the first local region of the metal oxide dielectric film; and
an upper branch electrode portion contacting the second local region of the metal oxide dielectric film,
wherein the doped silicon layer is apart from the second local region of the metal oxide dielectric film, the upper branch electrode portion being between the doped silicon layer and the second local region of the metal oxide dielectric film, and the doped silicon layer contacting the upper branch electrode portion.

3. The integrated circuit device of claim 1, comprising:
an interface dipole layer comprising a plurality of dipoles that are arranged along an interface between the second local region of the metal oxide dielectric film and the silicon oxide dielectric film,
wherein the metal-containing word line has a first length in a vertical direction, and
wherein each of the doped silicon layer and the interface dipole layer has a second length in the vertical direction that is less than the first length.

4. The integrated circuit device of claim 1, comprising:
a substrate, wherein a word line trench is in the substrate and extends in a first horizontal direction,
wherein the silicon oxide dielectric film, the metal oxide dielectric film, the metal-containing word line, and the doped silicon layer are in the word line trench.

5. The integrated circuit device of claim 1, comprising:
a substrate, wherein a word line trench is in the substrate and extends in a first horizontal direction,
wherein the metal-containing word line comprises:
a lower electrode portion arranged in a lower portion of the word line trench, the lower electrode portion having a plug shape and being free of inner space; and
two upper branch electrode portions integrally connected to the lower electrode portion, the two upper branch electrode portions being arranged in the word line trench and extending from the lower electrode portion, the two upper branch electrode portions and the lower electrode portion defining an upper internal space,
wherein the doped silicon layer is disposed in the upper internal space.

6. The integrated circuit device of claim 5, wherein, in the upper internal space, a width of the doped silicon layer along a second horizontal direction gradually increases as it extends away from the lower electrode portion in a vertical direction.

7. The integrated circuit device of claim 5, wherein, in the upper internal space, the doped silicon layer has a U-like cross-sectional shape.

8. The integrated circuit device of claim 1, comprising:
a substrate, wherein a word line trench is in the substrate and extends in a first horizontal direction,
wherein the metal-containing word line comprises:
a lower electrode portion in a lower portion of the word line trench, the lower electrode portion having a plug shape and being free of an inner spaced; and
two upper branch electrode portions integrally connected to the lower electrode portion, the two upper branch electrode portions being arranged in the word line trench and extending from the lower electrode portion, the two upper branch electrode portions and the lower electrode portion defining an upper internal space, the doped silicon layer being in the upper internal space,
wherein the integrated circuit device comprises:
an additional electrode layer arranged on the doped silicon layer in the upper internal space, the additional electrode layer being apart from each of the lower electrode portion and the two upper branch electrode portions, the doped silicon layer being between the additional electrode layer and the metal-containing word line,
wherein, in a vertical direction, an upper surface of the additional electrode layer is farther away from an entrance of the word line trench than an upper surface of each of the doped silicon layer and the two upper branch electrode portions.

9. The integrated circuit device of claim 1, comprising:
a substrate, wherein a word line trench is in the substrate, and wherein the silicon oxide dielectric film, the metal oxide dielectric film, the metal-containing word line, and the doped silicon layer are in the word line trench; and
an insulating capping pattern in the word line trench, the insulating capping pattern contacting each of an upper surface of the second local region of the metal oxide dielectric film, an upper surface of the metal-containing word line, and an upper surface of the doped silicon layer.

10. The integrated circuit device of claim 9, wherein, in the word line trench, the doped silicon layer has a U-like cross-sectional shape, the doped silicon layer defining an internal space, and
wherein the insulating capping pattern comprises:
a first portion having a lower surface that is in contact with each of the upper surface of the second local region of the metal oxide dielectric film, the upper surface of the metal-containing word line, and the upper surface of the doped silicon layer; and
a second portion integrally connected to the first portion and protruding to the internal space defined by the doped silicon layer, the second portion being in contact with the doped silicon layer in the internal space.

11. The integrated circuit device of claim 1, wherein the second local region of the metal oxide dielectric film comprises an upper second local region and a lower second local region, the first local region being between the upper second local region and the lower second local region.

12. The integrated circuit device of claim 11, wherein the doped silicon layer comprises:
a first doped silicon layer facing the upper second local region of the metal oxide dielectric film, the metal-containing word line being between the first doped silicon layer and the upper second local region of the metal oxide dielectric film; and
a second doped silicon layer facing the lower second local region of the metal oxide dielectric film, the metal-containing word line being between the second doped silicon layer and the lower second local region of the metal oxide dielectric film,
wherein the first doped silicon layer and the second doped silicon layer are apart from each other in a vertical direction.

13. The integrated circuit device of claim 11, comprising:
an additional electrode layer being apart from the metal-containing word line, the doped silicon layer being between the additional electrode layer and the metal-containing word line,
wherein the additional electrode layer extends parallel to the metal-containing word line and comprises a same material as the metal-containing word line.

14. An integrated circuit device comprising:
a substrate, wherein a word line trench is in the substrate and extends in a first horizontal direction;
a silicon oxide dielectric film covering an inner surface of the word line trench;
a metal oxide dielectric film being in contact with the silicon oxide dielectric film in the word line trench and being apart from the substrate, the silicon oxide dielectric film being between the metal oxide dielectric film and the substrate, the metal oxide dielectric film comprising a first local region and a second local region, the first local region being located in a lower portion of the word line trench, the second local region being closer to an entrance of the word line trench than the first local region, and the second local region having a dopant content ratio greater than a dopant content ratio of the first local region;
a metal-containing word line on the metal oxide dielectric film in the word line trench, the metal-containing word line being apart from the silicon oxide dielectric film, the metal oxide dielectric film being between the metal-containing word line and the metal oxide dielectric film; and
a doped silicon layer at least partially buried in the metal-containing word line in the word line trench, the doped silicon layer comprising a portion facing the second local region of the metal oxide dielectric film.

15. The integrated circuit device of claim 14, wherein the metal-containing word line comprises:
a lower electrode portion contacting the first local region of the metal oxide dielectric film; and
an upper branch electrode portion contacting the second local region of the metal oxide dielectric film,
wherein the doped silicon layer is apart from the second local region of the metal oxide dielectric film, the upper branch electrode portion being between the doped silicon layer and the second local region of the metal oxide dielectric film, the doped silicon layer contacting the upper branch electrode portion.

16. The integrated circuit device of claim 14, wherein the metal-containing word line has a first length in a vertical direction, and
wherein the doped silicon layer has a second length in the vertical direction that is less than the first length.

17. The integrated circuit device of claim 14, wherein the metal-containing word line comprises titanium nitride,
the metal oxide dielectric film comprises a titanium oxide film, and
each of the second local region of the metal oxide dielectric film and the doped silicon layer comprises at least one dopant including at least one of phosphorus, boron, arsenic, or germanium.

18. An integrated circuit device comprising:
a conductive line extending in a first horizontal direction;
a plurality of active regions over the conductive line, the plurality of active regions being apart from one another in the first horizontal direction, each of the plurality of active regions being connected to the conductive line;
a metal-containing word line between a pair of active regions of the plurality of active regions, the pair of active regions being adjacent to each other, the metal-containing word line extending in a second horizontal direction that is perpendicular to the first horizontal direction;
a silicon oxide dielectric film between a first active region of the pair of active regions and the metal-containing word line, the silicon oxide dielectric film covering a sidewall of the first active region;
a metal oxide dielectric film between the silicon oxide dielectric film and the metal-containing word line, the metal oxide dielectric film comprising a first local region and a second local region, the first local region being in contact with a first portion of the silicon oxide dielectric film, and the second local region being in contact with a second portion of the silicon oxide dielectric film, the second portion of the silicon oxide dielectric film being adjacent to the first portion of the silicon oxide dielectric film along a vertical direction, the second local region having a dopant content ratio greater than a dopant content ratio of the first local region; and
a doped silicon layer comprising a portion that faces the second local region of the metal oxide dielectric film, the metal-containing word line being between the portion of doped silicon layer and the second local region of the metal oxide dielectric film.

19. The integrated circuit device of claim 18, comprising:
an interface dipole layer,
wherein the second local region of the metal oxide dielectric film comprises an upper second local region and a lower second local region that are apart from each other in the vertical direction, the first local region being between the upper second local region and the lower second local region, and
wherein the interface dipole layer comprises:
a first interface dipole layer comprising a plurality of first dipoles that are arranged along an interface between the upper second local region of the metal oxide dielectric film and the silicon oxide dielectric film; and
a second interface dipole layer comprising a plurality of second dipoles that are arranged along an interface between the lower second local region of the metal oxide dielectric film and the silicon oxide dielectric film.

20. The integrated circuit device of claim 18, wherein the metal-containing word line comprises titanium nitride,
the metal oxide dielectric film comprises a titanium oxide film, and
each of the second local region of the metal oxide dielectric film and the doped silicon layer comprises at least one dopant including at least one of phosphorus, boron, arsenic, or germanium.
